(19) United States
(12) Patent Application Publication
(10) Pub. No.: US 2024/0014300 A1
(43) Pub. Date: Jan. 11, 2024

(54) SEMICONDUCTOR DEVICE AND METHOD FOR PRODUCING SEMICONDUCTOR DEVICE

(71) Applicant: ROHM CO., LTD., Kyoto-shi (JP)

(72) Inventor: Takayuki OSAWA, Kyoto-shi (JP)

(73) Assignee: ROHM CO., LTD., Kyoto-shi (JP)

(21) Appl. No.: 18/471,336

(22) Filed: Sep. 21, 2023

Related U.S. Application Data
(63) Continuation of application No. PCT/JP2022/007772, filed on Feb. 25, 2022.

(30) Foreign Application Priority Data
Mar. 26, 2021 (JP) 2021-053947

(51) Int. Cl. H01L 29/739; H01L 29/06; H01L 29/66

(52) U.S. Cl. CPC H01L 29/7397; H01L 29/0623; H01L 29/66348

(57) ABSTRACT

This semiconductor device comprises an active region and an outer peripheral region. The active region has a first-electroconductivity-type drift layer and a second-electroconductivity-type body layer. The active region has a main cell region having a main cell, a first insulating film covering the main cell, a first electrode part stacked on the first insulating film, a sense cell region having a sense cell, a second insulating film covering the sense cell, and a second electrode part stacked on the second insulating film. Between the main cell region and the sense cell region, there is formed a second-electroconductivity-type well region. The first electrode part and the second electrode part are electrically connected by the well region.

### CROSS-REFERENCE TO RELATED APPLICATIONS

This application is a continuation of International Application No. PCT/JP2022/007772, filed Feb. 25, 2022, which claims priority to JP 2021-053947, filed Mar. 26, 2021, the entire contents of each are incorporated herein by reference.

### BACKGROUND

### 1. Field

The present disclosure relates to a semiconductor device and a method for manufacturing the semiconductor device.

### 2. Description of Related Art

For example, a semiconductor device such as an insulated gate bipolar transistor (IGBT) is known to have a configuration including a current sense portion for detecting a main current flowing through the semiconductor device (see, for example, International Publication No. 2017/104516).

### BRIEF DESCRIPTION OF DRAWINGS

FIG. 1 is a plan view of a semiconductor device according to one embodiment.

FIG. 2 is a plan view showing a state in which a protective insulating film is omitted from the semiconductor device shown in FIG. 1.

FIG. 3 is a plan view schematically showing an active region, an outer peripheral region, and an intermediate region of the semiconductor device shown in FIG. 2.

FIG. 4 is a cross-sectional view taken along line 4-4 in FIG. 1, schematically showing a cross-sectional structure of the semiconductor device.

FIG. 5 is a cross-sectional view taken along line 5-5 in FIG. 1, schematically showing a cross-sectional structure of the semiconductor device.

FIG. 6 is a plan view showing a sense cell region and the structure surrounding it in an active region.

FIG. 7 is an enlarged view showing a part of FIG. 6.

FIG. 8 is a circuit diagram schematically showing a part of the circuit configuration of the semiconductor device.

FIG. 9 is an explanatory diagram illustrating an example of a manufacturing step of a method for manufacturing a semiconductor device.

FIG. 10 is an explanatory diagram illustrating an example of a manufacturing step of the method for manufacturing the semiconductor device.

FIG. 11 is an explanatory diagram illustrating an example of a manufacturing step of the method for manufacturing the semiconductor device.

FIG. 12 is an explanatory diagram illustrating an example of a manufacturing step of the method for manufacturing the semiconductor device.

FIG. 13 is an explanatory diagram illustrating an example of a manufacturing step of the method for manufacturing the semiconductor device.

FIG. 14 is an explanatory diagram illustrating an example of a manufacturing step of the method for manufacturing the semiconductor device.

FIG. 15 is an explanatory diagram illustrating an example of a manufacturing step of the method for manufacturing the semiconductor device.

FIG. 16 is an explanatory diagram illustrating an example of a manufacturing step of the method for manufacturing the semiconductor device.

FIG. 17 is an explanatory diagram illustrating an example of a manufacturing step of the method for manufacturing the semiconductor device.

FIG. 18 is a cross-sectional view schematically showing a cross-sectional structure of a main cell region and a sense cell region in an active region in a semiconductor device of a comparative example.

FIG. 19 is an enlarged plan view of a part of a sense cell region and the structure surrounding it in a semiconductor device according to a modification.

FIG. 20 is a cross-sectional view schematically showing a cross-sectional structure of a part of a main cell region in a semiconductor device according to a modification.

### DETAILED DESCRIPTION

A semiconductor device according to one embodiment will now be described with reference to the drawings. The embodiments described below exemplify configurations and methods for embodying a technical concept and are not intended to limit the material, shape, structure, layout, dimensions, and the like of each component to those described below.

Configuration of Semiconductor Device

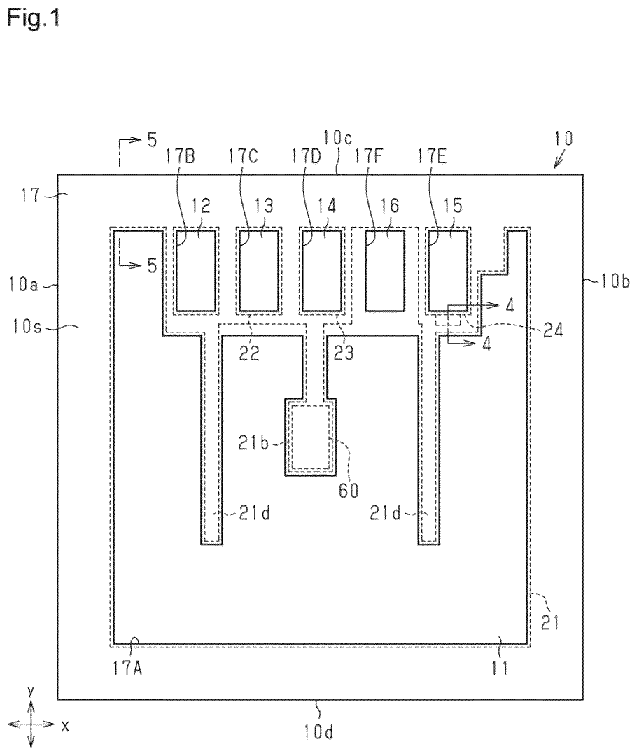

A schematic configuration of a semiconductor device 10 according to the present embodiment will be described with reference to FIGS. 1 to 5.

As shown in FIG. 1, the semiconductor device 10 is a trench-gate insulated gate bipolar transistor (IGBT). The semiconductor device 10 is used as a switching element in a vehicle on-board inverter device, for example. In this case, a current, for example, in a range of 5 A to 1000 A flows through the semiconductor device 10.

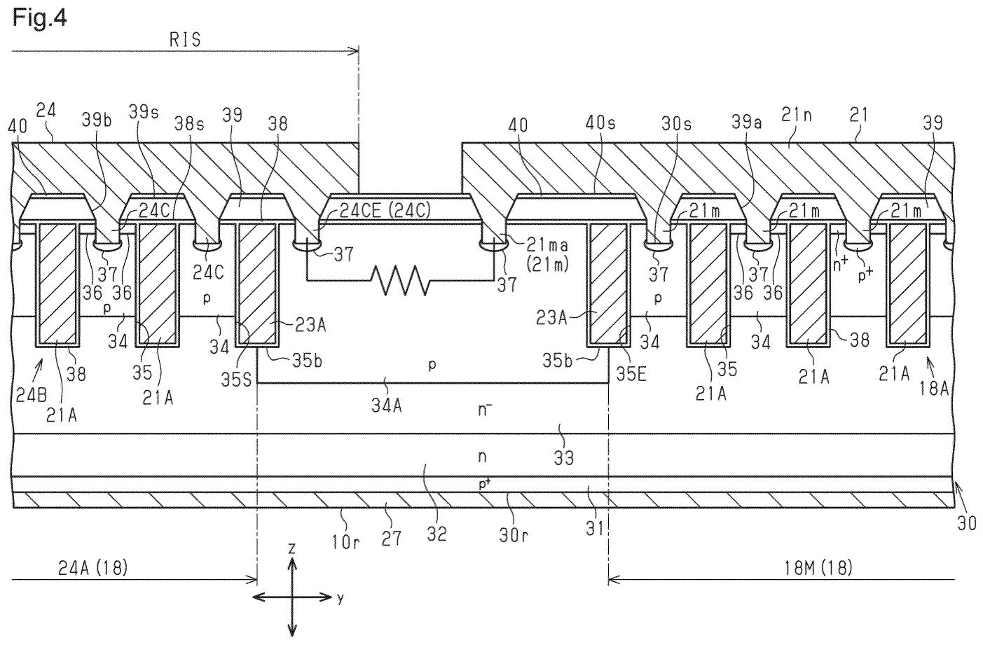

The semiconductor device 10 is shaped as a rectangular flat plate. The semiconductor device 10 includes a device main surface 10s, a device back surface 10r facing away from the device main surface 10s (see FIG. 4), and four device side surfaces 10a to 10d formed between the device main surface 10s and the device back surface 10r. The device side surfaces 10a to 10d are surfaces connecting the device main surface 10s and the device back surface 10r, for example, and are orthogonal to both the device main surface 10s and the device back surface 10r. The device main surface 10s is formed in, for example, a square shape. In the present embodiment, the length of a side of the device main surface 10s is approximately 11 mm. That is, the chip size of the semiconductor device 10 of the present embodiment is an 11 mm square. The chip size of the semiconductor device 10 can be changed freely.

In the following description, a direction in which the device main surface 10s and the device back surface 10r face is referred to as a z-direction. The z-direction may be referred to as a height direction of the semiconductor device 10. Two directions orthogonal to each other among the directions orthogonal to the z-direction are referred to as an x-direction and a y-direction. In the present embodiment, the device side surfaces 10a, 10b are opposite end surfaces of the semiconductor device 10 in the x-direction, and the device side surfaces 10c, 10d are opposite end surfaces of the semiconductor device 10 in the y-direction.

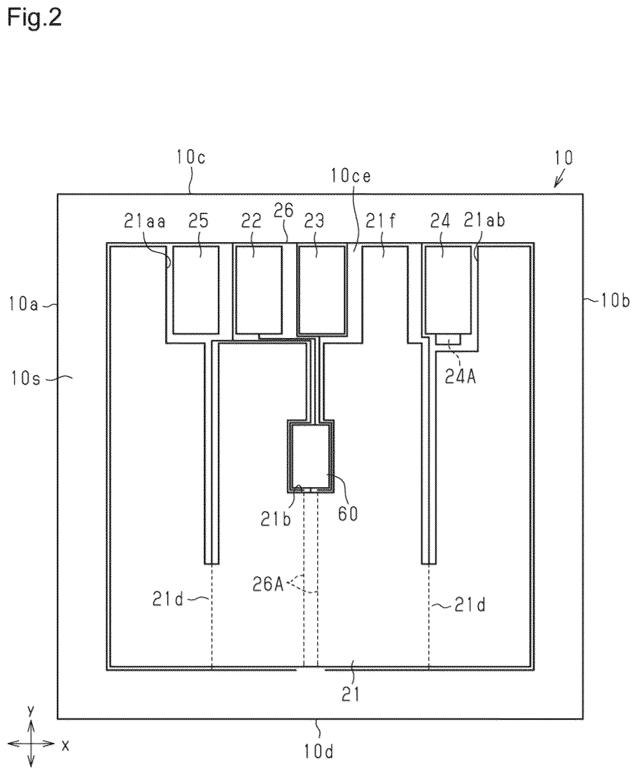

FIG. 2 shows an electrode configuration of the semiconductor device 10.

As shown in FIG. 2, the semiconductor device 10 includes an emitter electrode 21, an anode 22, a gate electrode 23, a current sense electrode 24, and a cathode 25. The semiconductor device 10 includes a temperature sensitive diode 60 for detecting the temperature of the semiconductor device 10. In the present embodiment, the emitter electrode 21 corresponds to a first electrode portion, and the current sense electrode 24 corresponds to a second electrode portion.

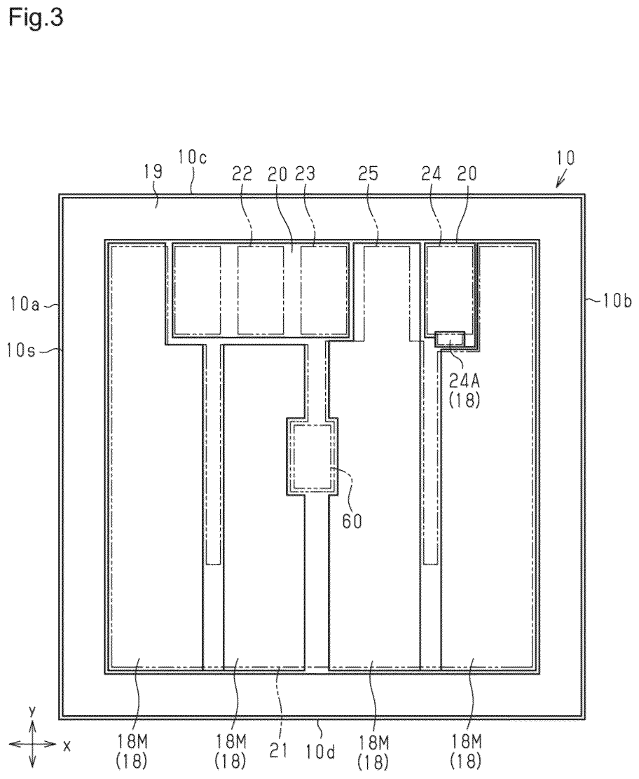

The semiconductor device 10 further includes a gate finger 26, which is electrically connected to the gate electrode 23. The gate finger 26 is configured for quickly supplying current supplied to the gate electrode 23 also to the main cell in a part of the emitter electrode 21 away from the gate electrode 23. As shown in FIG. 4, the semiconductor device includes a collector electrode 27. In the present embodiment, the collector electrode 27 is formed over the entire device back surface 10r. In FIGS. 1 and 3, the gate finger 26 is omitted for illustrative purposes.

When viewed in the z-direction, the emitter electrode 21 is formed over most of the device main surface 10s. Each of the cathode 25, the anode 22, the gate electrode 23, and the current sense electrode 24 is disposed in an electrode placement region 10ce. The electrode placement region 10ce is closer to one of the opposite ends in the y-direction of the device main surface 10s, specifically, to the device side surface 10c. The electrodes 22 to 25 are aligned with each other in the y-direction and spaced apart from each other in the x-direction.

The emitter electrode 21 includes electrode accommodating portions 21aa, 21ab, a diode arrangement portion 21b, and two gate finger accommodating portions 21d.

The electrode accommodating portions 21aa, 21ab are provided at one of the opposite ends in the y-direction of the emitter electrode 21 that is closer to the device side surface 10c. The electrode accommodating portion 21aa accommodates the cathode 25, the anode 22, and the gate electrode 23, and has a recessed shape. The electrode accommodating portion 21ab accommodates the current sense electrode 24 and has a recessed shape. The electrode accommodating portion 21aa is disposed closer to the device side surface 10a than the electrode accommodating portion 21ab is in the x-direction.

The cathode 25, the anode 22, the gate electrode 23, and the current sense electrode 24, which are accommodated in the electrode accommodating portions 21aa, 21ab, are aligned with each other in the y-direction and spaced apart from each other in the x-direction. In the present embodiment, the cathode 25, the anode 22, the gate electrode 23, and the current sense electrode 24 are arranged in the order of the cathode 25, the anode 22, the gate electrode 23, and the current sense electrode 24 from the device side surface 10a toward the device side surface 10b in the x-direction.

A part of the emitter electrode 21 between the electrode accommodating portion 21aa and the electrode accommodating portion 21ab in the x-direction serves as an emitter sense region 21f The emitter sense region 21f serves as an emitter sense electrode pad 16, which will be discussed below. The emitter sense region 21f serves as a part of the electrode accommodating portion 21aa and a part of the electrode accommodating portion 21ab. The emitter sense region 21f is formed between the gate electrode 23 and the current sense electrode 24 in the x-direction.

The diode arrangement portion 21b includes a part in which the temperature sensitive diode 60 is arranged, and is connected to the electrode accommodating portion 21aa. The diode arrangement portion 21b is provided substantially at the center of the emitter electrode 21 in the x-direction and the y-direction. Therefore, the temperature sensitive diode 60 is disposed substantially at the center of the emitter electrode 21 in the x-direction and the y-direction. Also, as shown in FIG. 2, the temperature sensitive diode 60 is disposed substantially at the center of the device main surface 10s in the x-direction and the y-direction.

The diode arrangement portion 21b is a part in which the emitter electrode 21 is not formed. A part of the diode arrangement portion 21b in which the temperature sensitive diode 60 is disposed is formed in a rectangular shape as viewed in the z-direction. Since the emitter electrode 21 defines the diode arrangement portion 21b, the emitter electrode 21 is formed so as to surround the temperature sensitive diode 60. The diode arrangement portion 21b extends in the y-direction from a part of the diode arrangement portion 21b in which the temperature sensitive diode 60 is arranged to the electrode accommodating portion 21aa, so as to be connected to the electrode accommodating portion 21aa.

The two gate finger accommodating portions 21d are disposed in a distributed manner on the opposite sides of the diode arrangement portion 21b in the x-direction. One of the gate finger accommodating portions 21d extends along the y-direction from the electrode accommodating portion 21aa, and the other gate finger accommodating portion 21d extends along the y-direction from the electrode accommodating portion 21ab. A part of the gate finger 26 is disposed in each of the gate finger accommodating portions 21d.

The gate finger accommodating portions 21d extend in the y-direction from the electrode accommodating portions 21aa, 21ab of the emitter electrode 21. The distal end portion of each gate finger accommodating portion 21d is disposed closer to the electrode accommodating portions 21aa, 21ab than one of the opposite ends in the y-direction of the emitter electrode 21 that is closer to the device side surface 10d is.

The gate finger 26 surrounds the emitter electrode 21 and extends into the two gate finger accommodating portions 21d and the diode arrangement portion 21b. The gate finger 26 in the diode arrangement portion 21b is formed so as to surround the temperature sensitive diode 60. The gate finger 26 includes a surface interconnection and an internal interconnection connected to the surface interconnection. The surface interconnection is made of, for example, a metal material, and the internal interconnection is made of, for example, polysilicon. The surface interconnection is provided at a position aligned with each of the electrodes 21 to 25 in the z-direction. The internal interconnection is disposed closer to the device back surface 10r in the z-direction than the metal interconnection is.

Gate fingers 26A are provided between a section including the diode arrangement portion 21b and the two gate finger accommodating portions 21d, and one of the opposite ends in the y-direction of the emitter electrode 21 that is closer to the device side surface 10d. The gate fingers 26A are formed by internal interconnections connected to the internal interconnection of the gate finger 26. That is, the gate fingers 26A do not have surface interconnections. Therefore, the gate fingers 26A are disposed closer to the device back surface 10r than the emitter electrode 21 is at positions overlapping with the emitter electrode 21 as viewed in the z-direction.

As shown in FIG. 1, a protective insulating film 17 is provided on the device main surface 10s to cover the electrodes 21 to 25. The protective insulating film 17 is an organic protective film that protects the semiconductor device 10 from the outside of the semiconductor device 10, and is made of a material including polyimide (PI), for example.

The protective insulating film 17 is provided with first to sixth openings 17A to 17F, which expose the respective electrodes 21 to 25. The electrodes 21 to 25, which are exposed by the first to sixth openings 17A to 17F, serve as pads to which conductive members from the outside of the semiconductor device 10 are bonded. Such pads include an emitter electrode pad 11, a cathode pad 12, an anode pad 13, a gate electrode pad 14, a current sense electrode pad 15, and an emitter sense electrode pad 16.

The first to sixth openings 17A to 17F provided in the protective insulating film 17 are disposed so as to be separated from each other as viewed in the z-direction.

The emitter electrode pad 11 is a part of the emitter electrode 21 that is exposed from the first opening 17A, and serves as the emitter of the IGBT. As shown in FIG. 1, the first opening 17A opens most of the emitter electrode 21. Most of the first opening 17A opens a part of the emitter electrode 21 that is closer to the device side surface 10d than to the electrode accommodating portions 21aa, 21ab. More specifically, the protective insulating film 17 is provided at each of a position overlapping with the two gate finger accommodating portions 21d and a position overlapping with the diode arrangement portion 21b and the gate fingers 26A as viewed in the z-direction.

The cathode pad 12 is a part of the emitter electrode 21 that is exposed from the second opening 17B, and serves as the cathode of the temperature sensitive diode 60. As shown in FIGS. 1 and 2, the second opening 17B opens an end of the emitter electrode 21 that is close to the device side surface 10a and the device side surface 10c. In other words, the second opening 17B opens a part of the emitter electrode 21 that is adjacent to and spaced apart from the anode 22 in the x-direction. The second opening 17B is provided at a position adjacent to and spaced apart from the first opening 17A in both the x-direction and the y-direction. That is, the cathode pad 12 is provided at a position adjacent to and spaced apart from the emitter electrode pad 11 in the y-direction.

The cathode pad 12 is disposed closer to the device side surface 10c than to the center of the device main surface 10s in the y-direction. The cathode pad 12 is adjacent to the anode 22 in the x-direction. The cathode pad 12 and the anode 22 are arranged side by side along the device side surface 10c as viewed in the z-direction.

The anode pad 13 is a part of the anode 22 that is exposed from the third opening 17C, and serves as the anode of the temperature sensitive diode 60. The third opening 17C is formed in a rectangular shape slightly smaller than the anode 22 as viewed in the z-direction.

The gate electrode pad 14 is a part of the gate electrode 23 that is exposed from the fourth opening 17D, and serves as the gate of the IGBT. The fourth opening 17D is formed in a rectangular shape slightly smaller than the gate electrode 23 as viewed in the z-direction.

The current sense electrode pad 15 is a part of the current sense electrode 24 that is exposed from the fifth opening 17E, and serve as a terminal from which information for detecting the current flowing through the IGBT is retrieved to the outside. The fifth opening 17E is formed in a rectangular shape slightly smaller than the current sense electrode 24 as viewed in the z-direction.

The emitter sense electrode pad 16 is a part of the emitter electrode 21 that is exposed from the sixth opening 17F. The sixth opening 17F is formed in a rectangular shape slightly smaller than the emitter sense region 21f as viewed in the z-direction.

As shown in FIG. 2, a part of the gate finger 26 extends from the gate electrode 23 toward the device side surface 10a and the device side surface 10d. More specifically, this part of the gate finger 26 extends from the gate electrode 23 toward the gate finger accommodating portion 21d closer to the device side surface 10a than the temperature sensitive diode 60 is in the y-direction, while detouring a part closer to the device side surface 10c than the anode 22 is. Another part of the gate finger 26 extends from the gate electrode 23 toward the device side surface 10b and the device side surface 10d. More specifically, the other part of the gate finger 26 extends from the gate electrode 23 toward the gate finger accommodating portion 21d closer to the device side surface 10b than the temperature sensitive diode 60 is in the y-direction, while detouring a part closer to the device side surface 10c than the emitter sense region 21f is.

As shown in FIG. 3, as viewed in the z-direction, the semiconductor device 10 includes an active region 18, an outer peripheral region 19, which surrounds the active region 18, and an intermediate region 20, which is surrounded by a main cell region 18M and the outer peripheral region 19. The active region 18, the outer peripheral region 19, and the intermediate region 20 are regions that appear divided when a semiconductor substrate (to be described below) of the semiconductor device 10 is viewed in the z-direction.

The active region 18 is a region in which a transistor is formed. The active region 18 is formed over most of the device main surface 10s. The active region 18 includes the main cell region 18M, in which main cells 18A (see FIG. 4) are formed, and a sense cell region 24A, in which sense cells 24B are formed. The sense cell region 24A is formed at a position away from the main cell region 18M.

The main cell region 18M is a region through which a main current flows. The main current is a current flowing from the collector electrode 27 toward the emitter electrode 21. In the present embodiment, the active region 18 is formed in a region overlapping with the emitter electrode 21 as viewed in the z-direction. In other words, the emitter electrode 21 covers the active region 18. On the other hand, the main cell region 18M is not formed at positions overlapping with the gate fingers 26A (see FIG. 2) in the z-direction even in the region overlapping with the emitter electrode 21.

The sense cell region 24A is a region through which a sense current corresponding to the main current flows. The sense cell region 24A is formed between the intermediate region 20 and the main cell region 18M in the y-direction. More specifically, the sense cell region 24A is formed between a region in the intermediate region 20 that overlaps with the current sense electrode 24 and the main cell region 18M that faces that region in the intermediate region 20 in the y-direction. The ratio of the sense current to the main current corresponds with the area ratio of the sense cell region 24A to the main cell region 18M. As shown in FIG. 3, the area of the sense cell region 24A is sufficiently smaller than that of the main cell region 18M. That is, the sense current, which is sufficiently smaller than the main current, flows through the sense cell region 24A. The sense cell region 24A is formed in a region that overlaps with the current sense electrode 24 as viewed in the z-direction. As shown in FIG. 1, the sense cell region 24A is formed at a position different from the fifth opening 17E. The sense cell region 24A is covered with the protective insulating film 17.

As shown in FIG. 3, the outer peripheral region 19 is a region in which a termination structure for improving the insulation withstand voltage of the semiconductor device 10 is provided. The outer peripheral region 19 is a region surrounding the emitter electrode 21 except for the region in which the electrodes 22 to 25 are formed. The main cells 18A are not formed in the outer peripheral region 19. As described above, the outer peripheral region 19 is a region outside the emitter electrode 21.

The intermediate region 20 is a region that overlaps with the cathode 25, the anode 22, the gate electrode 23, and the current sense electrode 24 as viewed in the z-direction. In other words, the cathode 25, the anode 22, the gate electrode 23, and the current sense electrode 24 each cover the intermediate region 20. The intermediate region 20 includes a region outside the main cell region 18M and the sense cell region 24A, in other words, a region in which the main cells 18A or the sense cells 24B are not formed.

FIG. 4 is a cross-sectional view taken along line 4-4 in FIG. 1, showing a cross-sectional structure of the semiconductor device 10. FIG. 4 schematically illustrates one example of the cross-sectional structure of the semiconductor device 10 in the main cell region 18M and the sense cell region 24A. In FIG. 4, the protective insulating film 17 is omitted for illustrative purposes.

As shown in FIG. 4, the semiconductor device 10 includes a semiconductor substrate 30. The semiconductor substrate 30 is made of, for example, a material containing n⁻-type silicon (Si). The semiconductor substrate 30 has a thickness in a range of 50 μm to 200 μm, for example.

The semiconductor substrate 30 includes a substrate surface 30s and a substrate back surface 30r, which face in opposite directions in the z-direction. Thus, the z-direction may be referred to as a thickness direction of the semiconductor substrate 30.

The semiconductor substrate 30 has a structure in which a p⁺-type collector layer 31, an n-type buffer layer 32, and an n⁻-type drift layer 33 are stacked in that order from the substrate back surface 30r toward the substrate surface 30s. Therefore, the main cell region 18M and the sense cell region 24A are both provided with the collector layer 31, the buffer layer 32, and the drift layer 33. The collector electrode 27 is formed on the substrate back surface 30r. The collector electrode 27 is formed over substantially the entire substrate back surface 30r. The surface of the collector electrode 27 opposite to the collector layer 31 serves as the device back surface 10r of the semiconductor device 10. In the present embodiment, the z-direction corresponds to the thickness direction of the drift layer 33. Therefore, “viewed in the z-direction” has the same meaning as “viewed in the thickness direction of the drift layer”.

As p-type impurity of the collector layer 31, for example, boron (B), aluminum (Al), or the like is used. The impurity concentration of the collector layer 31 is in a range of 1×10¹⁵ cm⁻³ to 2×10¹⁹ cm⁻³, for example.

As n-type impurity of the buffer layer 32 and the drift layer 33, nitrogen (N), phosphorus (P), arsenic (As), or the like is used. The impurity concentration of the buffer layer 32 is in a range of 1×10¹⁵ cm⁻³ to 5×10¹⁷ cm⁻³, for example. The impurity concentration of the drift layer 33 is lower than that of the buffer layer 32, and is in a range of 1×10¹³ cm⁻³ to 5×10¹⁴ cm⁻³, for example.

P-type base regions 34 are formed on the surface of the drift layer 33, that is, on the substrate surface 30s. The base regions 34 are formed over substantially the entire surfaces of both the main cell region 18M and the sense cell region 24A. The impurity concentration of the base regions 34 is in a range of 1×10¹⁶ cm⁻³ to 1×10¹⁸ cm⁻³, for example. The depth of each base region 34 from the substrate surface 30s is, for example, in a range of 1.0 μm to 4.0 μm. In the present embodiment, the base regions 34 correspond to a body layer of a second conductivity type.

Multiple trenches 35 are arranged side by side on the surfaces (substrate surface 30s) of the base regions 34 in both the main cell region 18M and the sense cell region 24A. The trenches 35 extend in the y-direction, for example, and are arranged to be spaced apart from each other in the x-direction. Thus, the stripe-shaped main cells 18A are defined in the main cell region 18M, and the stripe-shaped sense cells 24B are defined in the sense cell region 24A. In the main cell region 18M and the sense cell region 24A, the interval between the trenches 35 adjacent to each other in the x-direction (the center-to-center distance between the trenches 35) is, for example, in a range of 1.5 μm to 7.0 μm. The width of each trench 35 (the dimension of the trench 35 in the x-direction) is, for example, in a range of 0.5 μm to 3.0 μm. Each trench 35 extends through the base region 34 in the z-direction and extends to the middle of the drift layer 33. The trenches 35 in the main cell region 18M may be formed in a lattice shape so as to partition the main cells 18A in a matrix shape. Also, the trenches 35 in the sense cell region 24A may be formed in a lattice shape so as to partition the sense cells 24B in a matrix shape.

N⁺-type Emitter regions 36 are formed on the surfaces (substrate surface 30s) of the base regions 34 in the main cell region 18M and the sense cell region 24A. The emitter regions 36 are disposed on the opposite sides of each trench 35 in the x-direction. That is, the emitter regions 36 are provided on the opposite sides of the trench 35 in the arrangement direction of the trenches 35 in each base region 34. Therefore, two emitter regions 36 are disposed between each pair of the trenches 35 adjacent to each other in the x-direction so as to be spaced apart from each other in the x-direction. The depth of each emitter region 36 is in a range of 0.2 μm to 0.6 μm, for example. The impurity concentration of each emitter region 36 is higher than that of the base regions 34, and is in a range of 1×10¹⁹ cm⁻³ to 5×10²⁰ cm⁻³, for example.

P⁺-type base contact regions 37 are formed on the surfaces (substrate surfaces 30s) of the base regions 34 in the main cell region 18M and the sense cell region 24A. The base contact regions 37 are provided at positions adjacent to each emitter region 36 in the x-direction. That is, each base contact region 37 is provided between, in the x-direction, two of the emitter regions 36 provided between each pair of the trenches 35 adjacent to each other in the x-direction. The base contact regions 37 may be formed so as to be deeper than the emitter regions 36. The depth of each base contact region 37 is in a range of 0.2 μm to 1.6 μm, for example. The impurity concentration of each base contact region 37 is higher than that of the base regions 34, and is in a range of 5×10¹⁸ cm⁻³ to 1×10²⁰ cm⁻³, for example.

An insulating film 38 is integrally formed on both the inner surfaces of the trenches and the substrate surface 30s. The insulating film 38 contains, for example, silicon oxide (SiO₂). The thickness of the insulating film 38 is in a range of 1100 angstroms to 1300 angstroms. The insulating film 38 is formed so as to cover both the main cell region 18M and the sense cell region 24A.

An electrode material containing polysilicon or the like is embedded in each trench via the insulating film 38. The electrode material embedded in each trench 35 is electrically connected to one of the gate electrode 23 (gate finger 26) and the emitter electrode 21. In other words, a gate trench 23A and an emitter trench 21A are formed by the electrode material embedded in each trench 35. In both the main cell region 18M and the sense cell region 24A, the gate trenches 23A and the emitter trenches 21A are arranged in the same manner in the arrangement direction of the trenches 35. In both the main cell region 18M and the sense cell region 24A of the present embodiment, in the arrangement direction of the trenches 35, five trenches, or a gate trench 23A, an emitter trench 21A, an emitter trench 21A, an emitter trench 21A, and a gate trench 23A, are repeatedly arranged in the arrangement direction. In the present embodiment, both the gate trenches 23A and the emitter trenches 21A are buried up to the open end of each trench 35. In this manner, multiple main cells 18A are formed in the main cell region 18M, and multiple sense cells 24B are formed in the sense cell region 24A.

An intermediate insulating film 39 is formed on a surface 38s of the insulating film 38 provided on the substrate surface 30s. The intermediate insulating film 39 contains, for example, a SiO₂. A barrier layer 40 for preventing the intermediate insulating film 39 from being charged by external ions is formed on the surface 39s of the intermediate insulating film 39. The barrier layer 40 is formed of a material having a diffusion coefficient smaller than those of the protective insulating film 17, the insulating film 38, and the intermediate insulating film 39. The barrier layer 40 is made of, for example, a material including silicon nitride (SiN). The emitter electrode 21 is formed on a surface 40s of the barrier layer 40. That is, the intermediate insulating film 39 is an interlayer insulating film that fills the space between the emitter electrode 21 and the gate trench 23A. The thickness of the intermediate insulating film 39 is thicker than the thickness of the insulating film 38. The thickness of the intermediate insulating film 39 is thicker than the thickness of the barrier layer 40. The thickness of the intermediate insulating film 39 is in a range of 3000 angstroms to 15000 angstroms, for example. In the present embodiment, a part of the laminated structure of the insulating film 38, the intermediate insulating film 39, and the barrier layer 40 that covers the main cell region 18M corresponds to a first insulating film, and a part of the laminated structure that covers the sense cell region 24A corresponds to a second insulating film. That is, in the present embodiment, both the first insulating film and the second insulating film have a laminated structure of the insulating film 38, the intermediate insulating film 39, and the barrier layer 40.

The laminated structure of the insulating film 38, the intermediate insulating film 39, and the barrier layer 40 includes multiple contact holes 39a, 39b, which extend through the insulating film 38, the intermediate insulating film 39, and the barrier layer 40 in the z-direction.

The contact holes 39a are openings provided in the laminated structure of the insulating film 38, the intermediate insulating film 39, and the barrier layer 40, which covers the main cell region 18M. The contact holes 39a are provided at positions overlapping with the base contact regions 37 of the main cell region 18M as viewed in the z-direction. Thus, the base contact regions 37 are exposed from the laminated structure of the insulating film 38, the intermediate insulating film 39, and the barrier layer 40. The emitter electrode 21 is formed on the surface 40s of the barrier layer 40 and is connected to the base contact regions 37 through the contact holes 39a.

The contact holes 39b are openings provided in the laminated structure of the insulating film 38, the intermediate insulating film 39, and the barrier layer 40, which covers the sense cell region 24A. The contact holes 39b are provided at positions overlapping with the base contact regions 37 of the sense cell region 24A as viewed in the z-direction. Thus, the base contact regions 37 are exposed from the laminated structure of the insulating film 38, the intermediate insulating film 39, and the barrier layer 40. The current sense electrode 24 is formed on the surface 40s of the barrier layer 40 and is connected to the base contact regions 37 through the contact holes 39b.

In the present embodiment, the emitter electrode 21 has a laminated structure of a barrier metal layer and a metal interconnection layer formed on the barrier metal layer, although not illustrated. The barrier metal layer is made of a material containing titanium nitride (TiN), for example. The metal interconnection layer is made of a material containing an alloy of aluminum and copper (AlCu), for example. The emitter electrode 21 includes contacts 21m embedded in the contact holes 39a and a laminated electrode portion 21n stacked on the barrier layer 40. The contacts 21m and the laminated electrode portion 21n are integrated with each other. The contacts 21m and the laminated electrode portion 21n are both formed by a laminated structure of a barrier metal layer and a metal interconnection layer. Thus, in the present embodiment, the contact holes 39a each correspond to a main-side opening, and the contact holes 39b each correspond to a sense-side opening.

As shown in FIG. 4, the current sense electrode 24 is electrically connected to the sense cells 24B in the sense cell region 24A. The sense cell region 24A is formed at a position that overlaps with the current sense electrode 24 as viewed in the z-direction.

The current sense electrode 24 has the same configuration as that of the emitter electrode 21 and has a laminated structure of a barrier metal layer and a metal interconnection layer. Like the emitter electrode 21, the current sense electrode 24 includes contacts 24C, at which the current sense electrode 24 partly enters the contact holes 39b. The contacts 24C are in contact with the base contact regions 37 of the sense cell region 24A.

Although not illustrated, the current sense electrode 24 is electrically connected to an external integrated circuit (IC) by, for example, wires. The integrated circuit is connected to a microcomputer via shunt resistors, for example, and detects a current generated in the sense cell region 24A. The magnitude of the main current flowing through the main cells 18A is detected by multiplying the magnitude of the detected current by the area ratio between the sense cell region 24A and the main cell region 18M. When the detected main current is greater than or equal to a specified current value, the operation of the semiconductor device 10 is stopped, so that the semiconductor device 10 is protected from damage due to an overcurrent.

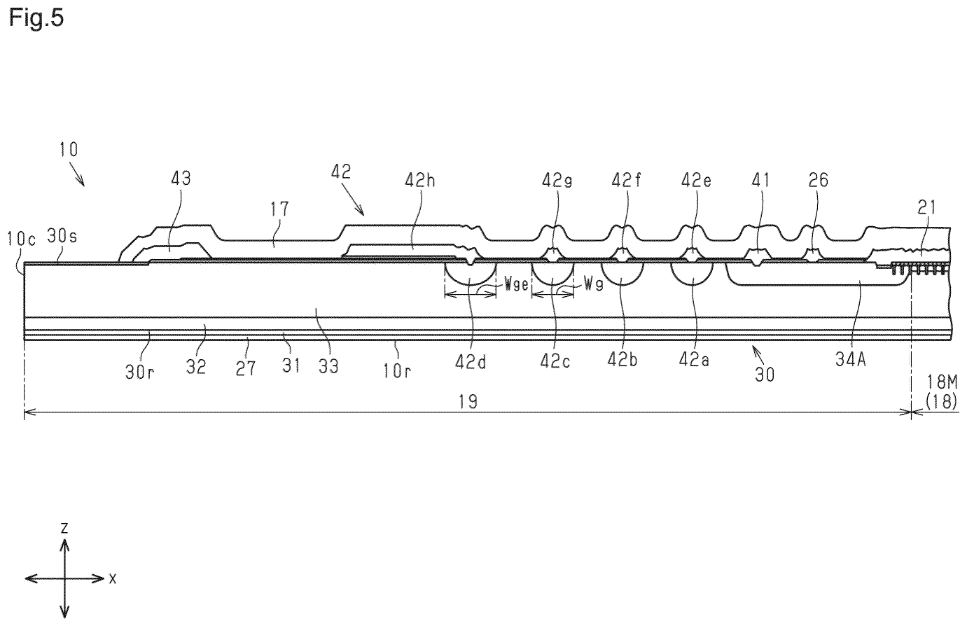

A schematic configuration of the outer peripheral region 19 will be described with reference to FIG. 5. FIG. 5 shows a cross-sectional structure of a part of the outer peripheral region 19.

As illustrated in FIG. 5, the gate finger 26, an emitter routing portion 41, a field limiting ring (FLR) portion 42, and an equipotential ring 43 are provided in the outer peripheral region 19. In the present embodiment, each of the gate finger 26, the emitter routing portion 41, and the equipotential ring 43 has a laminated structure of a barrier metal layer and a metal interconnection layer, which is the same configuration as the emitter electrode 21.

A p-type well region 34A, which is a semiconductor region of the second conductivity type, is formed in a section of the outer peripheral region 19 that is adjacent to the main cell region 18M. The well region 34A is formed so as to surround the main cell region 18M, for example. The well region 34A is formed so as to be closer to the substrate back surface 30r than the trenches 35 of the main cell region 18M are. Therefore, the well region 34A is formed so as to be closer to the substrate back surface 30r than the base regions 34 of the main cell region 18M are. The impurity concentration of the well region 34A is lower than the impurity concentration of the base regions 34.

The gate finger 26 and the emitter routing portion 41 are formed at positions overlapping with the well region 34A as viewed in the z-direction. The emitter routing portion 41 is disposed outward of the gate finger 26. The emitter routing portion 41 is integrated with the emitter electrode 21 and is formed in an annular shape to surround the gate finger 26.

The FLR portion 42 and the equipotential ring 43 are formed outward of the well region 34A.

The FLR portion 42 is a termination structure for improving the withstand voltage of the semiconductor device 10, and is provided outward of the emitter routing portion 41. The FLR portion 42 is formed in an annular shape surrounding the emitter electrode 21 and the electrodes 22 to 24. In the present embodiment, the FLR portion 42 is formed so as to have a closed annular shape. The FLR portion 42 improves the withstand voltage of the semiconductor device 10 by relaxing the electric field in the outer peripheral region 19 and limiting the influence from external ions.

The FLR portion 42 includes multiple (four, in the present embodiment) annular conductors and semiconductor regions arranged to be spaced apart from each other.

Multiple (four, in the present embodiment) annular guard rings 42a to 42d are formed on the substrate surface 30s of the semiconductor substrate 30. In the present embodiment, the guard rings 42a to 42d are each formed in a closed ring shape as viewed in the z-direction. The guard rings 42a to 42d are partially formed in the drift layer 33. The guard rings 42a to 42d are semiconductor regions of the second conductivity type (p-type, in the present embodiment), and are arranged so as to be separated from each other in a direction orthogonal to the z-direction. The guard rings 42a to 42d are arranged in the order of the guard ring 42a, the guard ring 42b, the guard ring 42c, and the guard ring 42d in a direction away from the emitter electrode 21. The width Wge of the outermost guard ring 42d is larger than the width Wg of the other guard rings 42a to 42c. As p-type impurity of the guard rings 42a to 42d, B, Al, or the like is used. The impurity concentration of the guard rings 42a to 42d is the same as the impurity concentration of the base regions 34, for example, and is in a range of 1×10¹⁶ cm⁻³ to 1×10¹⁸ cm⁻³, for example. Therefore, the impurity concentration of the guard rings 42a to 42d is higher than the impurity concentration of the well region 34A. In other words, the impurity concentration of the well region 34A is lower than the impurity concentration of the guard rings 42a to 42d.

The FLR portion 42 includes field plates 42e to 42h provided in correspondence with the guard rings 42a to 42d. As viewed in the z-direction, the field plate 42e is provided at a position overlapping with the guard ring 42a, the field plate 42f is provided at a position overlapping with the guard ring 42b, the field plate 42g is provided at a position overlapping with the guard ring 42c, and the field plate 42h is provided at a position overlapping with the guard ring 42d. The field plate 42e is in contact with the guard ring 42a, the field plate 42f is in contact with the guard ring 42b, the field plate 42g is in contact with the guard ring 42c, and the field plate 42h is in contact with the guard ring 42d. The field plates 42e to 42h are each formed so as to have a closed annular shape as viewed in the z-direction.

The equipotential ring 43 is a termination structure for improving the withstand voltage of the semiconductor device 10, and is formed in an annular shape so as to surround the FLR portion 42. The equipotential ring 43 is formed in an outer peripheral part of the outer peripheral region 19. In the present embodiment, the equipotential ring 43 is formed so as to have a closed annular shape as viewed in the z-direction. The equipotential ring 43 improves the withstand voltage of the semiconductor device 10.

The equipotential ring 43 includes a channel stop region of a first conductivity type (n⁺-type) formed on the surface of the drift layer 33 (substrate surface 30s), an internal interconnection provided in the insulating film 38 and the intermediate insulating film 39, and a surface interconnection provided on the surface 40s of the barrier layer 40. The surface interconnection is electrically connected to the internal interconnection via an opening extending through the intermediate insulating film 39. The surface interconnection is electrically connected to the channel stop region via an opening extending through both the intermediate insulating film 39 and the insulating film 38.

As shown in FIG. 5, in the semiconductor device 10, the protective insulating film 17 covers a part of the emitter electrode 21, a part of each of the electrodes 22 to 25, the gate finger 26, the emitter routing portion 41, the FLR portion 42, and the equipotential ring 43.

Current Sense Electrode and Surrounding Structure

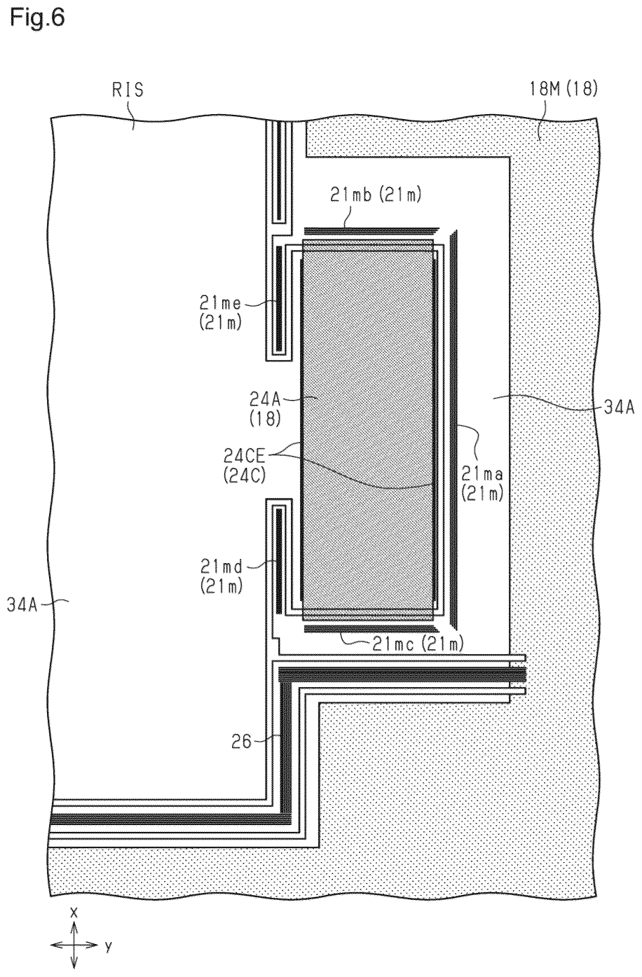

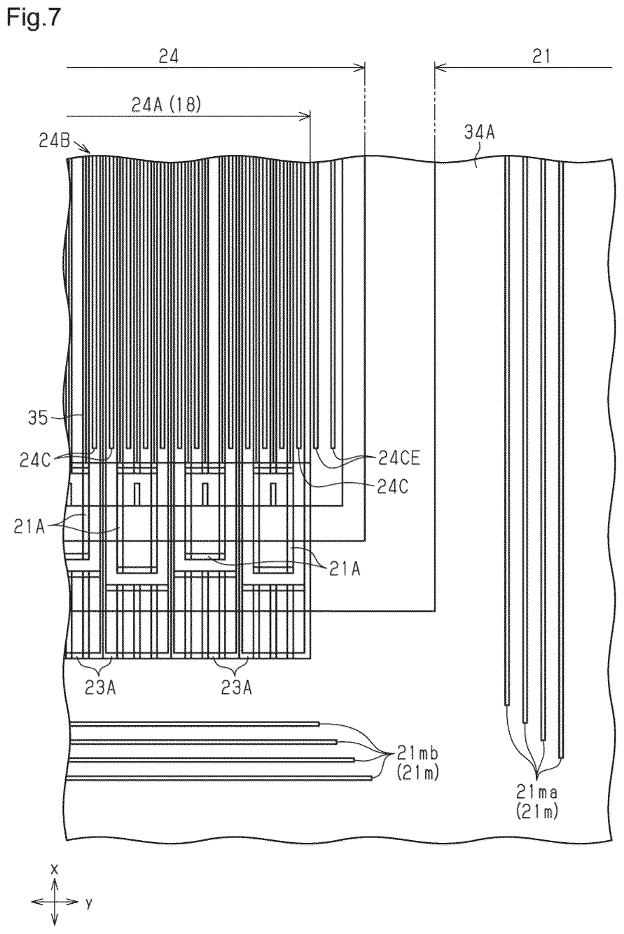

A region RIS of the semiconductor device 10, in which the current sense electrode 24 is formed, will now be described with reference to FIGS. 4, 6, and 7. FIG. 6 is an enlarged plan view of one of the opposite ends in the y-direction of the current sense electrode 24 that is closer to the device side surface 10d. FIG. 7 is an enlarged view of a part of the current sense electrode 24 shown in FIG. 6, particularly, the sense cell region 24A and the surrounding area.

As shown in FIGS. 2 and 6, the sense cell region 24A, in which the main cells 18A (see FIG. 4) are formed, is formed in the region RIS of the semiconductor substrate 30. The sense cell region 24A is formed at one of the opposite ends in the y-direction of the region RIS that is closer to the device side surface 10d (see FIG. 2). The well region 34A is formed in a region other than the sense cell region 24A in the region RIS in the semiconductor substrate 30. That is, the sense cell 24B (see FIG. 4) is not formed in a region other than the sense cell region 24A in the region RIS.

As shown in FIGS. 4 and 7, the sense cells 24B are provided side by side in the y-direction in the sense cell region 24A. The sense cells 24B have the same configuration as the main cells 18A (see FIG. 5). The sense cells 24B are provided to extend in the x-direction. Therefore, the multiple trenches 35, extending in the x-direction, are arranged side by side at intervals in the y-direction. Each group of a specified number of the trenches 35, arranged side by side, is connected together at the opposite ends in the x-direction.

As shown in FIGS. 4 and 6, the well region 34A is formed between the sense cell region 24A and the corresponding main cell region 18M in the y-direction. More specifically, as shown in FIG. 4, the well region 34A is formed between a first trench 35E and a second trench 35S. The first trench 35E is one of the trenches 35 in the main cell region 18M that is closest to the sense cell region 24A. The second trench 35S is one of the trenches in the sense cell region 24A that is closest to the main cell region 18M. The well region 34A is formed so as to be closer to the substrate back surface 30r than the first trench 35E and the second trench 35S are. That is, in the depth direction of each of the trenches 35E, the well region 34A is formed so as to be deeper than a bottom 35b of each of the trenches 35E, 35S. In other words, the well region 34A is formed closer to the drift layer 33 than the bottom 35b of each of the trenches 35E, 35S is.

In each main cell region 18M, the emitter regions 36 are not formed between the first trench 35E and the trenches 35 adjacent to the first trench 35E. That is, the first trench is a trench 35 provided in each main cell region 18M and is a trench different from the trenches 35 in the main cells 18A.

Also, in the sense cell region 24A, the emitter regions 36 are not formed between the second trench 35S and the trenches 35 adjacent to the second trench 35S. That is, the second trench 35S is a trench 35 provided in the sense cell region 24A and is a trench different from the trenches 35 in the sense cells 24B.

The impurity concentration of the well region 34A is lower than the impurity concentration of the guard rings 42a to 42d. Therefore, the impurity concentration of the well region 34A is lower than the impurity concentrations of both of the guard rings 42a to 42d and the base regions 34.

In the present embodiment, the gate trench 23A is formed by the electrode material embedded in the first trench 35E, and the gate trench 23A is formed by the electrode material embedded in the second trench 35S. Thus, in the present embodiment, the trenches 35 at the outer edge of both the main cell region 18M and the sense cell region 24A serve as the gate trenches 23A.

At least one of the first trench 35E and the second trench 35S may be formed by an emitter trench 21A. That is, the trenches 35 at the outer edge of both the main cell region 18M and the sense cell region 24A may be emitter trenches 21A.

The well region 34A is formed at a position overlapping with each of the trenches 35E, 35S as viewed in the z-direction. As viewed in the z-direction, the well region 34A does not protrude from the first trench 35E toward the main cell region 18M in the y-direction. As viewed in the z-direction, the well region 34A does not protrude from the second trench 35S toward the sense cell region 24A in the y-direction. In this manner, the well region 34A is formed so as to cover a part of the bottom 35b of each of the trenches 35E, 35S.

As shown in FIG. 4, the emitter electrode 21 extends toward the sense cell region 24A beyond the first trench 35E of the main cell region 18M. The current sense electrode 24 extends toward the main cell region 18M beyond the second trench 35S of the sense cell region 24A. The emitter electrode 21 and the current sense electrode 24 are spaced apart from each other in the y-direction.

As viewed in the z-direction, the well region 34A has a part overlapping with the current sense electrode 24 and a part overlapping with the emitter electrode 21. That is, as viewed in the z-direction, the well region 34A has parts overlapping with both the current sense electrode 24 and the emitter electrode 21. That is, as viewed in the z-direction, the emitter electrode 21 has a part that protrudes toward the sense cell region 24A beyond the main cell region 18M in the y-direction. As viewed in the z-direction, the current sense electrode 24 has a part that protrudes toward the main cell region 18M beyond the sense cell 24A in the y-direction.

The main cell region 18M is formed at a position opposed to the sense cell region 24A via the well region 34A in the y-direction. More specifically, as shown in FIG. 6, the main cell region 18M is formed so as to surround the sense cell region 24A on three sides that are the device side surfaces 10a, 10b, and 10d (see FIG. 2). The well region 34A is formed between the sense cell region 24A and the main cell region 18M. Since the well region 34A is also formed in a part overlapping with the current sense electrode 24, the well region 34A is formed so as to surround the sense cell region 24A as viewed in the z-direction.

As shown in FIG. 7, multiple contacts 24C are provided, and multiple trenches 35 in the sense cell region 24A are provided. In the present embodiment, the contacts 24C and the trenches 35 in the sense cell region 24A extend in the x-direction. The contacts 24C and the trenches 35 in the sense cell region 24A are alternately arranged in the y-direction.

As shown in FIGS. 4 and 6, the semiconductor device 10 includes end contacts 24CE provided on the opposite sides in the y-direction of the current sense electrode 24. The end contacts 24CE are provided at positions away from the sense cell region 24A. More specifically, the end contacts 24CE are disposed between the sense cell region 24A and the main cell region 18M in the y-direction. As viewed in the z-direction, the end contacts 24CE are disposed at positions overlapping with a region of the well region 34A that is adjacent to the sense cell region 24A in the y direction. The end contacts 24CE extend in the x-direction like the contacts 24C. In the present embodiment, the length of the end contacts 24CE in the x-direction is equal to the length of the contacts 24C in the x-direction. In the present embodiment, the end contacts 24CE each correspond to a sense end contact.

The distance between the end contact 24CE and the contact 24C adjacent to the end contact 24CE in the y-direction is equal to the distance between the contacts 24C adjacent to each other in the y-direction. In the present embodiment, as shown in FIG. 7, two end contacts 24CE are provided at positions overlapping with a region of the well region 34A that is adjacent to the sense cell region 24A in the y-direction. In FIG. 6, a structure in which one end contact 24CE is provided is shown from the viewpoint of easy understanding of the drawing.

As shown in FIG. 6, the contacts 21m of the emitter electrode 21 are arranged in the well region 34A. The emitter electrode 21 is electrically connected to the well region 34A by the contacts 21m. The contacts 21m are provided at positions overlapping with both the well region 34A and the emitter electrode 21 as viewed in the z-direction. The emitter electrode 21 is provided with multiple contacts 21m. The contacts 21m disposed in the well region 34A and away from the main cell region 18M of the emitter electrode 21 are referred to as first contacts 21ma, second contacts 21mb, third contacts 21mc, fourth contacts 21md, and fifth contacts 21me. In the present embodiment, these contacts 21ma, 21mb, 21mc, 21md, 21me correspond to main contacts.

The first contacts 21ma are disposed in the well region 34A and between the sense cell region 24A and the main cell region 18M in the y-direction. The first contacts 21ma are arranged closer to the sense cell region 24A than to the main cell region 18M. The first contacts 21ma extend in the x-direction. In other words, the first contacts 21ma extend parallel to the end contacts 24CE. The first contacts 21ma extend parallel to both the trenches 35 in the sense cell region 24A (see FIG. 4) and the trenches 35 in the main cell region 18M. The first contacts 21ma extend in the long side direction of the rectangular sense cell region 24A as viewed in the z-direction.

In the present embodiment, the length of the first contacts 21ma in the x-direction is longer than the length of the end contacts 24CE in the x-direction. The length of the first contacts 21ma in the x-direction is longer than the length of the sense cell region 24A in the x-direction. As shown in FIG. 7, multiple first contacts 21ma are provided. The first contacts 21ma are arranged to be spaced apart from each other in the y-direction.

As viewed in the z-direction, the first contacts 21ma are provided at positions opposed to the end contacts 24CE in the y-direction. In the present embodiment, the number of the first contacts 21ma is greater than the number of the end contacts 24CE. In the present embodiment, the first contacts 21ma correspond to main end contacts.

As shown in FIG. 6, each of the second contacts 21mb and the third contacts 21mc is arranged in the well region 34A and between the sense cell region 24A and the main cell region 18M in the x-direction. The second contacts 21mb are arranged closer to the device side surface 10a (see FIG. 1) than the sense cell region 24A is, and the third contacts 21mc are arranged closer to the device side surface 10b (see FIG. 1) than the sense cell region 24A is. Each of the second contacts 21mb and the third contacts 21mc is arranged closer to the sense cell region 24A than to the main cell region 18M. Each of the second contacts 21mb and the third contacts 21mc extends in the y-direction. That is, both the second contacts 21mb and the third contacts 21mc extend in a direction orthogonal to the end contacts 24CE. Both the second contacts 21mb and the third contacts 21mc extend parallel to both the trenches 35 in the sense cell region 24A (see FIG. 4) and the trenches 35 in the main cell region 18M. Both the second contacts 21mb and the third contacts 21mc extend in the short side direction of the rectangular sense cell region 24A as viewed in the z-direction.

In the present embodiment, the length of the second contacts 21mb in the y-direction and the length of the third contacts 21mc in the y-direction are equal to each other. Each of the length of the second contacts 21mb in the y-direction and the length of the third contacts 21mc in the y-direction is shorter than the length of the first contacts 21ma in the x-direction.

As shown in FIG. 7, multiple second contacts 21mb are provided. The second contacts 21mb are arranged to be spaced apart from each other in the x-direction. Although not illustrated, multiple third contacts 21mc are provided. The third contacts 21mc are arranged to be spaced apart from each other in the x-direction. In the present embodiment, the number of the second contacts 21mb is greater than the number of the end contacts 24CE. The number of the third contacts 21mc is greater than the number of the end contacts 24CE.

As shown in FIG. 6, each of the fourth contacts 21md and the fifth contacts 21me is arranged on the side opposite of the sense cell region 24A from the main cell region 18M in the y-direction. The fourth contacts 21md and the fifth contacts 21me are arranged to be spaced apart from each other in the x-direction while being aligned with each other in the y-direction. Each of the fourth contacts 21md and the fifth contacts 21me extends in the x-direction. In other words, both the fourth contacts 21md and the fifth contacts 21me extend parallel to the end contacts 24CE. Both the fourth contacts 21md and the fifth contacts 21me extend parallel to both the trenches 35 in the sense cell region 24A (see FIG. 4) and the trenches 35 in the main cell region 18M. Both the fourth contacts 21md and the fifth contacts 21me extend in the long side direction of the rectangular sense cell region 24A as viewed in the z-direction.

Although not illustrated, multiple fourth contacts 21md and multiple fifth contacts 21me are provided. The fourth contacts 21md are arranged to be spaced apart from each other in the y-direction. The fifth contacts 21me are arranged to be spaced apart from each other in the y-direction. In the present embodiment, the number of the fourth contacts 21md is greater than the number of the end contacts 24CE. The number of the fifth contacts 21me is greater than the number of the end contacts 24CE.

As shown in FIG. 6, the first to fifth contacts 21ma to 21me are arranged to surround the sense cell region 24A. That is, the emitter electrode 21 is formed so as to surround the sense cell region 24A. As viewed in the z-direction, the part of the emitter electrode 21 that surrounds the sense cell region 24A has an open annular shape having a space between the fourth contacts 21md and the fifth contacts 21me in the x-direction. The current sense electrode 24 extends to a position overlapping with the sense cell region 24A via a gap in the x-direction between the fourth contacts 21md and the fifth contacts 21me in the emitter electrode 21.

As shown in FIG. 4, the end contacts 24CE of the current sense electrode 24 and the first contacts 21ma of the emitter electrode 21 are connected to the well region 34A. That is, the current sense electrode 24 and the emitter electrode 21 are electrically connected to each other via the well region 34A. Therefore, as shown in FIG. 4, the emitter electrode 21 and the current sense electrode 24 are electrically connected to each other via a resistance component of the well region 34A. Although not illustrated, the second contacts 21mb, the third contacts 21mc, the fourth contacts 21md, and the fifth contacts 21me of the emitter electrode 21 are also connected to the well region 34A. Thus, the emitter electrode 21 is electrically connected to the current sense electrode 24 via the contacts 21mb to 21me and the well region 34A.

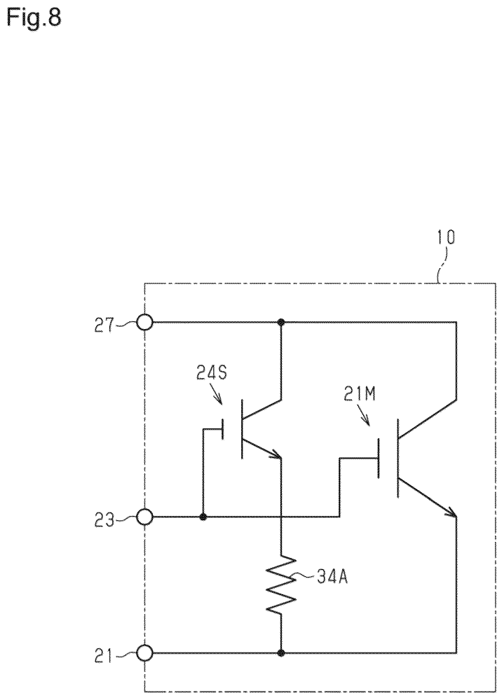

As shown in FIG. 8, a sense IGBT 24S, which includes the sense cells 24B of the sense cell region 24A, is connected in parallel with a main IGBT 21M, which includes the main cells 18A of the main cell region 18M in the semiconductor device 10. The gate of the sense IGBT 24S and the gate of the main IGBT 21M are both electrically connected to the gate electrode 23.

Method of Manufacturing Semiconductor Device

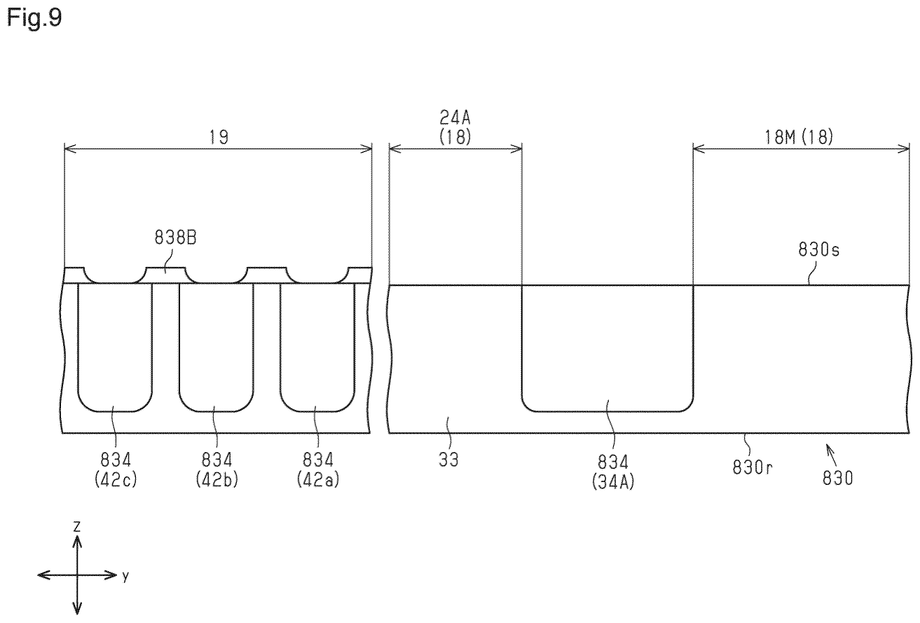

Referring to FIGS. 9 to 17, a method of manufacturing the semiconductor device according to the present embodiment will be described. For illustrative purposes, the configuration of the semiconductor device 10 used to show the manufacturing process is simplified in FIGS. 9 to 17. Accordingly, the shapes of the components of the semiconductor device 10 in FIGS. 9 to 17 may be different from the shapes of the components of the semiconductor device 10 in FIGS. 1 to 7. FIGS. 9 to 17 show respective manufacturing steps of a part of the main cell region 18M and the sense cell region 24A and a part of the FLR portion 42. In the following description, a method of manufacturing a single semiconductor device 10 will be described with reference to FIGS. 9 to 17. The method of manufacturing the semiconductor device 10 of the present embodiment is not limited to manufacture of a single semiconductor device 10, but may be manufacturing multiple semiconductor devices 10.

The method for manufacturing the semiconductor device 10 of the present embodiment includes a step of preparing a semiconductor substrate 830 made of a material containing Si. The semiconductor substrate 830 includes an n⁻-type drift layer 33 as a semiconductor layer of the first conductivity type. The drift layer 33 is formed over the entire semiconductor substrate 830. In other words, the drift layer 33 is formed in both the main cell region 18M and the sense cell region 24A. The semiconductor substrate 830 includes a substrate surface 830s and a substrate back surface 830r, which face in opposite directions in the thickness direction (z-direction). Therefore, the substrate surface 830s is the surface of the drift layer 33. As shown in FIG. 9, the method of manufacturing the semiconductor device 10 includes a step of forming a substrate insulating film 830B on a part of the substrate surface 838s of the semiconductor substrate 830 that corresponds to the outer peripheral region 19. A substrate insulating film 838B is formed by thermally oxidizing the semiconductor substrate 830 and then performing wet etching and dry etching in that order.

As shown in FIG. 9, the method of manufacturing the semiconductor device 10 of the present embodiment includes a step of forming p-type well regions 834 as semiconductor regions of the second conductivity type in the semiconductor substrate 830. Specifically, a p-type impurity is selectively injected into the substrate surface 830s of the semiconductor substrate 830. Subsequently, the p-type impurity is diffused by thermally treating the semiconductor substrate 830. Through the steps described above, the well regions 834 are formed. The well regions 834 are partially formed in the drift layer 33. The surface of the well regions 834 serve as the substrate surface 830s and are therefore continuous with the surface of the drift layer 33. The well regions 834 include the well region 34A and the guard rings 42a to 42d (the guard ring 25d is not shown in FIG. 9). That is, the well region 34A and the guard rings 42a to 42d are formed in the same step.

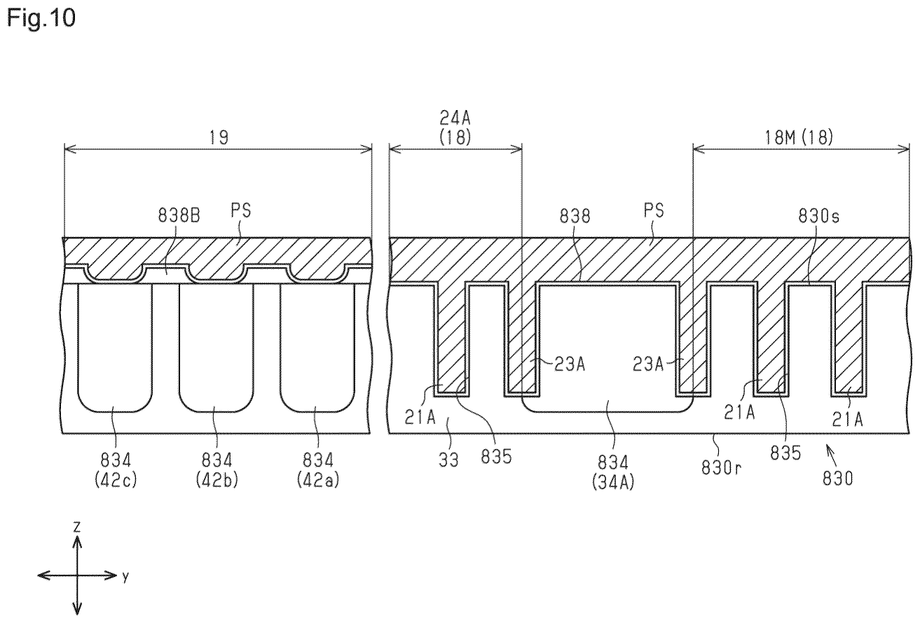

As shown in FIG. 10, the method of manufacturing the semiconductor device 10 of the present embodiment includes a step of forming trenches 835 in the semiconductor substrate 830, a step of forming an insulating film 838, and a step of forming electrodes.

First, a trench mask (not shown) is formed on the substrate surface 830s of the semiconductor substrate 830. Subsequently, the trench mask is selectively etched. That is, as viewed in the z-direction, regions in the trench mask in which the trenches 835 are formed are etched. Accordingly, regions in the substrate surface 830s of the semiconductor substrate 830 where the trenches 835 are to be formed are exposed in the trench mask. Subsequently, regions in the substrate surface 830s of the semiconductor substrate 830 where the trenches 835 are to be formed are etched. Accordingly, the trenches 835 are formed in both the main cell region 18M and the sense cell region 24A of the semiconductor substrate 830.

Subsequently, the semiconductor substrate 830 is thermally oxidized to form an oxide film on the entire surface of the semiconductor substrate 830 including the inner surface of each trench 835. This forms the insulating film 838 in the main cell region 18M of the substrate surface 830s of the semiconductor substrate 830. The insulating film 838 in the main cell region 18M is a gate insulating film and is also formed on the inner surface of each trench 835. In the outer peripheral region 19 of the semiconductor substrate 830, the insulating film 838 is stacked on the surface of the substrate insulating film 838B.

Subsequently, an electrode material PS such as polysilicon is embedded in each trench 835 and is formed on the substrate surface 830s of the semiconductor substrate 830. As a result, the gate trenches 23A and the emitter trenches 21A are formed.

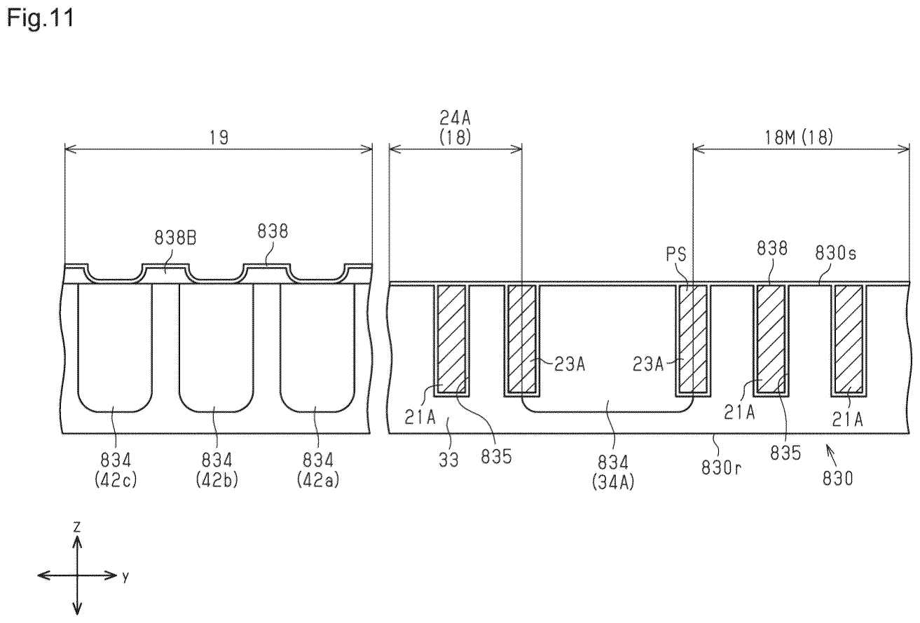

As shown in FIG. 11, the method of manufacturing the semiconductor device 10 of the present embodiment includes a step of etching the electrode material PS and a step of forming the insulating film 838 on the electrode material PS.

Specifically, first, the electrode material PS of the main cell region 18M of the substrate surface 830s of the semiconductor substrate 830 and the region of the outer peripheral region 19 other than the gate finger 26 and the gate electrode 23 is removed by etching. Subsequently, the electrode material embedded in each trench 835 is oxidized. This forms the insulating film 838 on each electrode material PS.

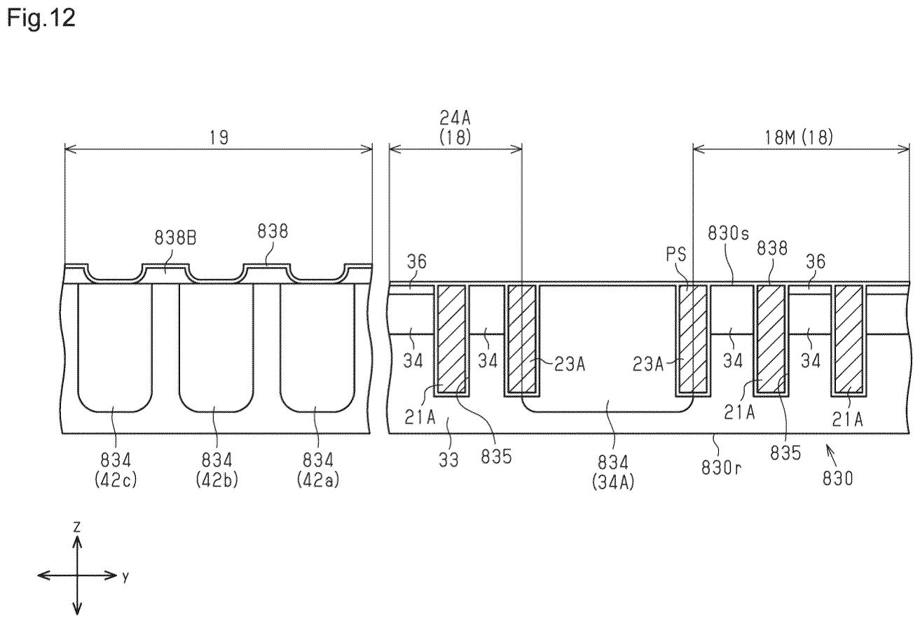

As shown in FIG. 12, the method of manufacturing the semiconductor device 10 of the present embodiment includes a step of forming the base regions 34 and the emitter regions 36. Specifically, ion implantation of n-type and p-type impurities is selectively performed to the substrate surface 830s of the semiconductor substrate 830 and the impurities are diffused, to form the p-type base regions 34 and the n⁺-type emitter regions 36 in that order.

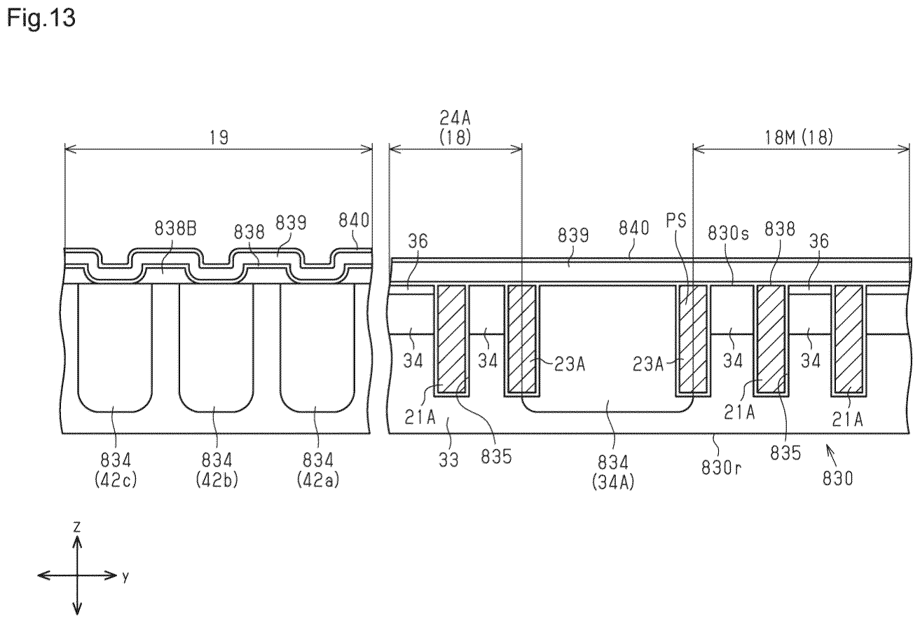

As shown in FIG. 13, the method of manufacturing the semiconductor device 10 of the present embodiment includes a step of forming an intermediate insulating film 839 and a step of forming a barrier layer 840.

First, the intermediate insulating film 839 as a silicon oxide film is formed on the entire substrate surface 830s of the semiconductor substrate 830 by, for example, chemical vapor deposition (CVD). The intermediate insulating film 839 is stacked on the insulating film 838. In this case, in the main cell region 18M and the sense cell region 24A, an insulating film having a two-layer structure is formed that includes the insulating film 838 and the intermediate insulating film 839, which are formed on the substrate surface 830s of the semiconductor substrate 830. On the other hand, in the outer peripheral region 19, an insulating film having a three-layer structure is formed that includes the substrate insulating film 838B, the insulating film 838, and the intermediate insulating film 839, which are formed on the substrate surface 830s of the semiconductor substrate 830.

Subsequently, a barrier layer 840 as a silicon nitride film is formed over the entire surface of the intermediate insulating film 839 by sputtering, for example. The barrier layer 840 is stacked on the intermediate insulating film 839. The barrier layer 840 is formed on the surface of the intermediate insulating film 839 by CVD, for example.

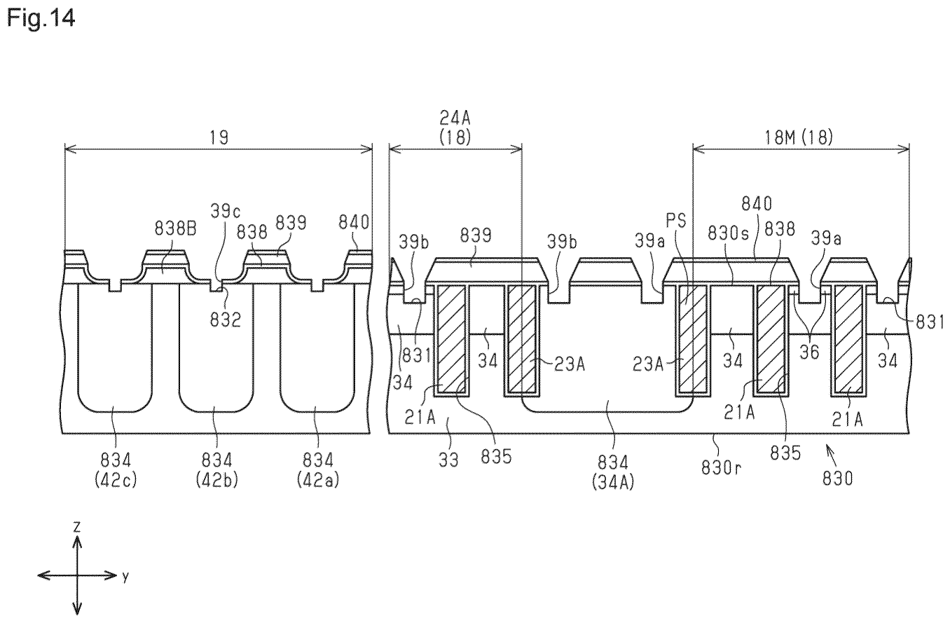

As shown in FIG. 14, the method of manufacturing the semiconductor device 10 of the present embodiment includes a step of forming contact holes.

Contact holes 39a, 39b are respectively formed in the main cell region 18M and the sense cell region 24A by etching so as to extend through the barrier layer 840, the intermediate insulating film 839, and the insulating film 838. Both the contact holes 39a in the main cell region 18M and the contact holes 39b in the sense cell region 24A expose the base regions 34. The contact holes 39a, 39b form recesses 831 in the substrate surface 830s of the semiconductor substrate 830 corresponding to the base regions 34.

The contact holes 39a, 39b are formed in the outer peripheral region 19 by etching so as to extend through the barrier layer 840, the intermediate insulating film 839, the insulating film 838, and the substrate insulating film 838B. The contact holes 39c in the outer peripheral region 19 individually expose, for example, the guard rings 42a to 42d. The contact holes 39c form recesses 832 in the substrate surface 830s of the semiconductor substrate 830 corresponding to the guard rings 42a to 42d.

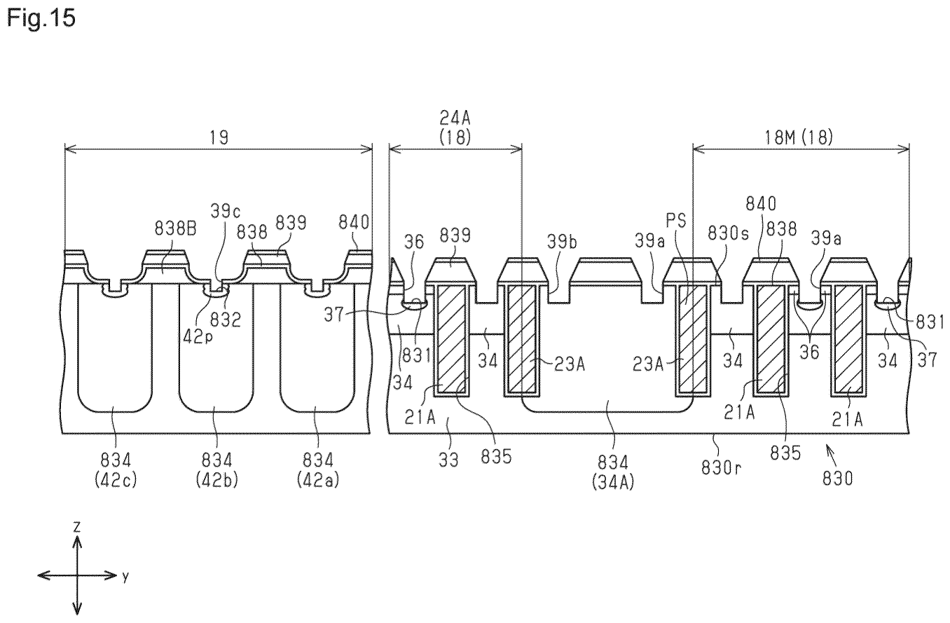

As shown in FIG. 15, the method of manufacturing the semiconductor device 10 of the present embodiment includes a step of forming the base contact regions 37 and contact regions 42p. Specifically, ion implantation of p-type impurities is performed to the substrate surface 830s of the semiconductor substrate 830 through an opening and the impurities are diffused, to form the p⁺-type base contact regions 37 and contact regions 42p.

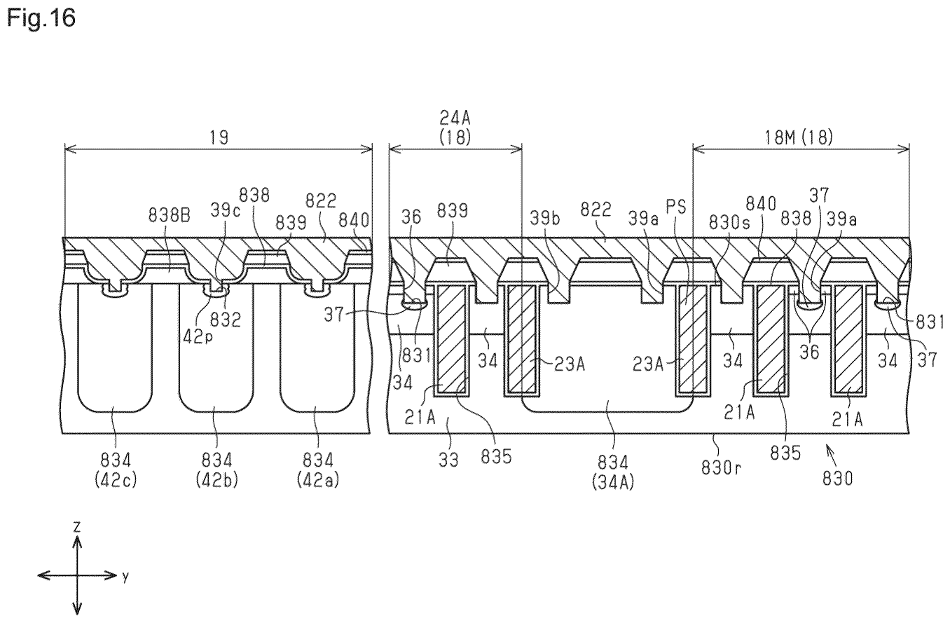

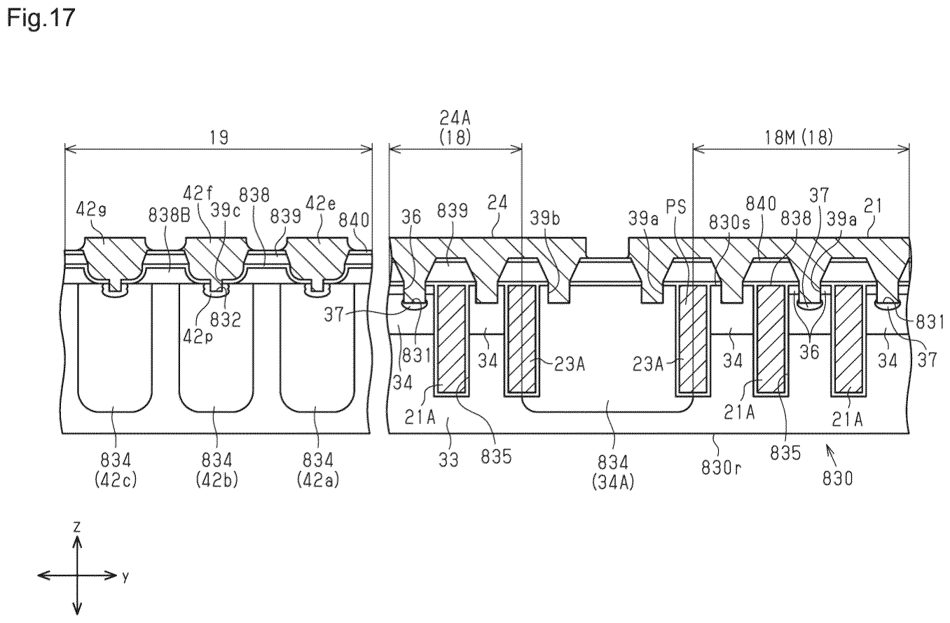

As shown in FIGS. 16 and 17, the method of manufacturing the semiconductor device 10 of the present embodiment includes a step of forming the emitter electrode 21, the electrodes 22 to 24, the gate finger 26, the field plates 42e to 42h, and the equipotential ring 43. FIGS. 16 and 17 show the steps of forming the emitter electrode 21, the current sense electrode 24, and the field plates 42e to 42g.

As shown in FIG. 16, first, a metal layer 822 is formed on the surface 40s of the barrier layer 40 and the contact holes 39a to 39c. More specifically, a thin first metal layer is formed on the surface 40s of the barrier layer 40 and the inner surfaces of the contact holes 39a to 39c by sputtering using titanium (Ti), for example. Subsequently, a thin second metal layer is formed on the first metal layer by sputtering using titanium nitride (TiN). Subsequently, plug electrodes made of tungsten (W) are embedded in the contact holes 39a to 39c. Then, an electrode layer is formed by sputtering using AlSiCu. The metal layer 822 is thus formed. The metal layer 822 is formed over the entire barrier layer 40 as viewed in the z-direction.

As shown in FIG. 17, the emitter electrode 21, the electrodes 22 to 24, the gate finger 26, the field plates 42e to 42h, and the equipotential ring 43 are formed by etching the metal layer 822 (see FIG. 16). FIG. 17 shows the emitter electrode 21, the current sense electrode 24, and the field plates 42e to 42g.

Although not illustrated, the method of manufacturing the semiconductor device 10 of the present embodiment includes a step of forming the protective insulating film 17. Specifically, a passivation layer containing an organic material such as polyimide is formed over the entire substrate surface 830s of the semiconductor substrate 830 so as to cover the emitter electrode 21, the electrodes 22 to 25, the gate finger 26, the field plates 42e to 42h, and the equipotential ring 43 as viewed in the z-direction. Subsequently, openings are formed by etching so as to expose the emitter electrode 21, the cathode 25, the anode 22, the gate electrode 23, and the current sense electrode 24. Thus, the protective insulating film 17, the emitter electrode pad 11, the cathode pad 12, the anode pad 13, the gate electrode pad 14, the current sense electrode pad 15, and the emitter sense electrode pad 16 are formed. The protective insulating film 17 covers a part of the emitter electrode 21, parts of the electrodes 22 to 25, the gate finger 26, the field plates 42e to 42h, and the equipotential ring 43.

Although not illustrated, the method of manufacturing the semiconductor device 10 of the present embodiment includes a step of forming the buffer layer 32, the collector layer 31, and the collector electrode 27. Specifically, ion implantation of n-type and p-type impurities is selectively performed to the substrate back surface of the semiconductor substrate 830 and the impurities are diffused, to form the buffer layer 32 and the collector layer 31 in that order. Subsequently, the collector electrode 27 is formed on the surface of the collector layer 31 opposite to the buffer layer 32. The semiconductor device 10 is manufactured through the above steps. FIGS. 9 to 17 show part of the manufacturing steps of the semiconductor device 10, and the manufacturing method of the semiconductor device 10 may include steps not shown in FIGS. 9 to 17.

Operation

Operation of the semiconductor device 10 of the present embodiment will now be described.

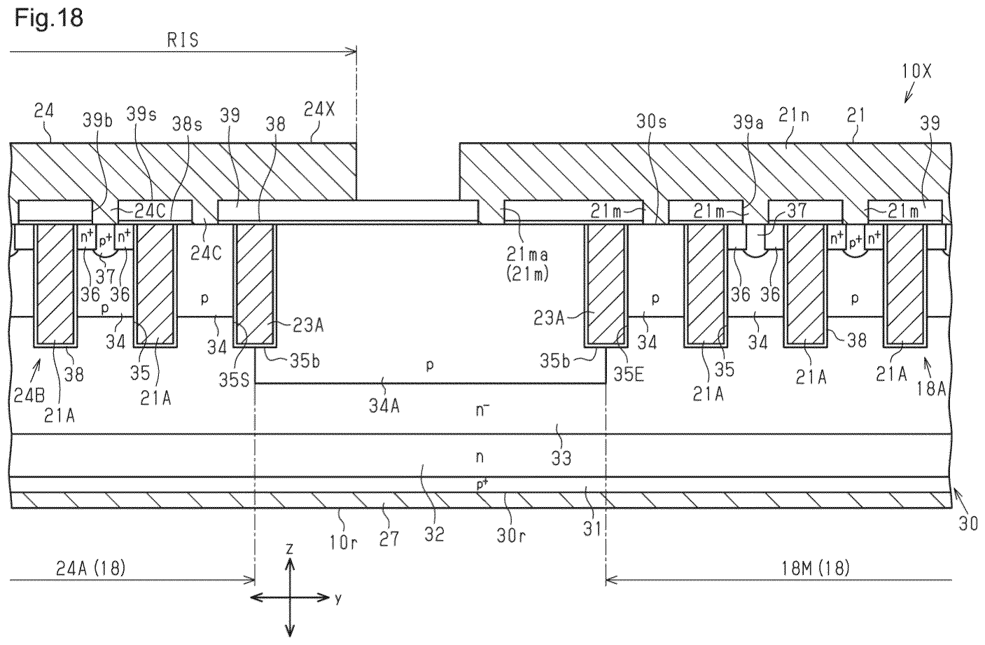

FIG. 18 is a diagram of a semiconductor device 10X of a comparative example, illustrating a cross-sectional structure of an emitter electrode 21 and a current sense electrode 24X in an outer peripheral region 19.

The current sense electrode 24X is electrically connected to a sense cell region 24A by contacts 24C, but is not electrically connected to a well region 34A. That is, the current sense electrode 24X does not have an end contact 24CE. Therefore, in the semiconductor device 10X of the comparative example, the current sense electrode 24X and the emitter electrode 21 are not electrically connected to each other.

In the semiconductor device 10X of the comparative example, changes in the gate voltage cause noise and surge due to the gate capacitance. Such noise and surge affect the sense cell region 24A. Specifically, the noise and surge are superimposed on the current flowing through the sense cell region 24A. This causes the electric potential of the current sense electrode 24X to change with respect to the electric potential of the emitter electrode 21. Thus, in the semiconductor device 10X of the comparative example, the detection accuracy of the current flowing through the main cell region 18M may decrease.

On the other hand, in the semiconductor device 10 of the present embodiment, the current sense electrode 24 and the emitter electrode 21 are electrically connected to each other via the end contact 24CE and the well region 34A. Since the well region 34A has a relatively low impurity concentration, the well region 34A is a resistance component having a relatively high impedance in the conductive path between the current sense electrode 24 and the emitter electrode 21. Accordingly, the current sense electrode 24 and the emitter electrode 21 are electrically connected to each other via a resistance component having a relatively high impedance.

Advantages

The semiconductor device 10 according to the present embodiment has the following advantages.

(1) The semiconductor device 10 includes the main cell region 18M, which includes the main cells 18A, the sense cell region 24A, which includes the sense cells 24B and detects the main current, and the p-type well region 34A, which is formed between the main cell region 18M and the sense cell region 24A. The main cell region 18M has the laminated structure of the insulating film 38, the intermediate insulating film 39, and the barrier layer 40, which covers the main cells 18A, and the emitter electrode 21, which is stacked on the laminated structure of the insulating film 38, the intermediate insulating film 39, and the barrier layer 40. The sense cell region 24A has the laminated structure of the insulating film 38, the intermediate insulating film 39, and the barrier layer 40, which covers the sense cells 24B, and the current sense electrode 24, which is stacked on the laminated structure. The emitter electrode 21 and the current sense electrode 24 are electrically connected to the well region 34A.

With this configuration, since the emitter electrode 21 and the current sense electrode 24 are electrically connected to each other via the well region 34A, the electric potential of the current sense electrode 24 is prevented from changing with respect to the electric potential of the emitter electrode 21. The semiconductor device 10 according to the present embodiment prevents the detection accuracy of the current flowing through the main cell region 18M from decreasing.

(2) The emitter electrode 21 and the current sense electrode 24 are electrically connected to each other via the resistance component of the well region 34A.

With this configuration, the electric potential of the current sense electrode 24 is prevented from changing with respect to the electric potential of the emitter electrode 21 due to the resistance component of the well region 34A. The semiconductor device 10 according to the present embodiment prevents the detection accuracy of the current flowing through the main cell region 18M from decreasing.

(3) As viewed in the z-direction, the well region 34A has parts overlapping with both the emitter electrode 21 and the current sense electrode 24.

This configuration allows the well region 34A and the emitter electrode 21 to be easily connected to each other by the contacts 21m, and allows the well region 34A and the current sense electrode 24 to be easily connected to each other by the end contacts 24CE.

(4) The well region 34A is formed between the first trench 35E and the second trench 35S. The first trench 35E is one of the trenches 35 of the main cell region 18M that is closest to the sense cell region 24A. The second trench 35S is one of the trenches 35 of the sense cell region 24A that is closest to the main cell region 18M.

With this configuration, since the well region 34A is formed so as to connect the main cell region 18M and the sense cell region 24A, the emitter electrode 21 and the current sense electrode 24 are easily connected to the well region 34A.

(5) The impurity concentration of the well region 34A is lower than the impurity concentration of the base regions 34.

With this configuration, the well region 34A, which serves as a conductive path between the emitter electrode 21 and the current sense electrode 24, is a resistor having a relatively high impedance. This prevents the electric potential of the current sense electrode 24 from changing with respect to the electric potential of the emitter electrode 21.

(6) The emitter electrode 21 includes the contacts 21m, which are connected to the well region 34A. The contacts 21m are formed so as to surround the sense cell region 24A.

With this configuration, since the number of conductive paths between the well region 34A and the emitter electrode 21 increases, it is possible to increase the number of contacts for collecting current from the collector electrode 27 to the emitter electrode 21 via the well region 34A. Therefore, since the current flowing from the collector electrode 27 to the emitter electrode 21 when the semiconductor device 10 breaks down can be dispersed by the contacts, heat generation due to current concentration is reduced.

(7) The impurity concentration of the well region 34A is lower than the impurity concentration of the guard rings 42a to 42d.

With this configuration, the well region 34A, which serves as a conductive path between the emitter electrode 21 and the current sense electrode 24, is a resistor having a relatively high impedance. This prevents the electric potential of the current sense electrode 24 from changing with respect to the electric potential of the emitter electrode 21.

(8) The insulating film covering the main cell region 18M and the insulating film covering the sense cell region 24A are both formed by the insulating film 38 and the intermediate insulating film 39.

With this configuration, the manufacturing process of the semiconductor device 10 is simplified as compared with the case in which the insulating film covering the main cell region 18M and the insulating film covering the sense cell region 24A are formed separately. This reduces the manufacturing costs of the semiconductor device 10.

(9) The method of manufacturing the semiconductor device 10 includes the step of forming the contact holes 39a, 39b in a part of the laminated structure of the intermediate insulating film 39, the insulating film 38, and the barrier layer 40 that covers the well region 34A, the step of forming the contacts 21m, which are in contact with the well region 34A, by embedding parts of the emitter electrode 21 in the contact holes 39a, and the step of forming the contacts 24C, which are in contact with the well region 34A, by embedding parts of the current sense electrode 24 in the contact holes 39b. This configuration achieves the same advantage as the above-described advantage (1).

[Modifications]

The above-described embodiment exemplifies, without any intention to limit, applicable forms of a semiconductor device and a method of manufacturing the semiconductor device according to the present disclosure. The semiconductor device and the method of manufacturing the semiconductor device according to the present disclosure can be applicable to forms differing from the above-described embodiment. In an example of such a form, the structure of the embodiment is partially replaced, changed, or omitted, or a further structure is added to the above-described embodiment. The modifications described below may be combined with one another as long as there is no technical inconsistency. In the modifications, the same reference characters are given to those components that are the same as the corresponding components of the above-described embodiment. Such components will not be described in detail.

In the above-described embodiment, the number of end contacts 24CE closer to the main cell region 18M among the end contacts 24CE of the current sense electrode 24 can be changed. In one example, the number of the end contacts 24CE may be one, or may be greater than two.

In the above-described embodiment, the number of the first contacts 21ma can be changed. In one example, the number of the first contacts 21ma may be equal to the number of the end contacts 24CE of the current sense electrode 24 or may be less than the number of the end contacts 24CE. The number of the second to fifth contacts 21mb to 21me can also be changed, and can be changed in the same manner as the first contacts 21ma.

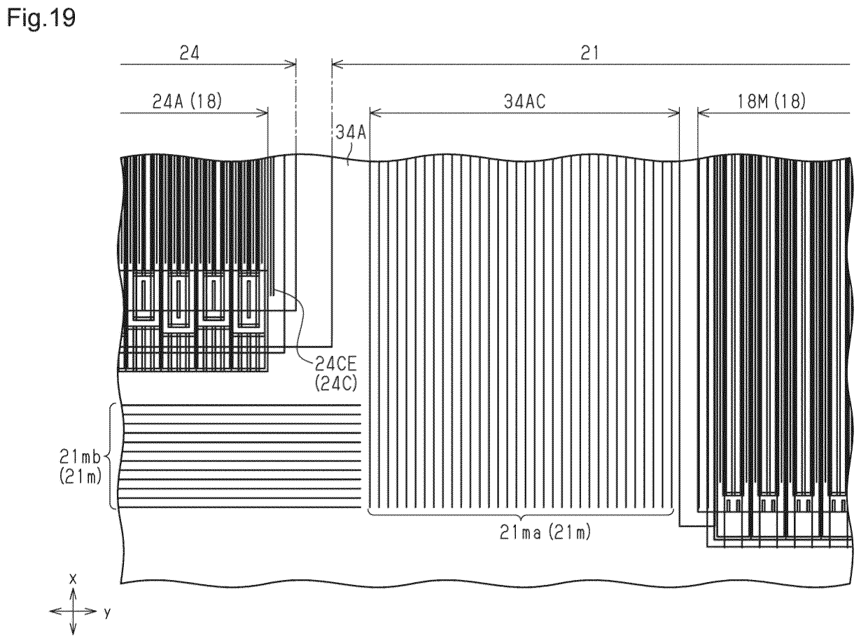

In the above-described embodiment, as shown in FIG. 19, the first contacts 21ma may be formed over the entire region 34AC between the main cell region 18M and the sense cell region 24A in the y-direction in the well region 34A. Specifically, the first contacts 21ma are arranged to be spaced apart from each other in the y-direction in the region 34AC. Further, as shown in FIG. 19, the number of the second contacts 21mb may be increased.

With this configuration, it is possible to increase the number of contacts for collecting current from the collector electrode 27 to the emitter electrode 21 via the well region 34A. Therefore, since the current flowing from the collector electrode 27 to the emitter electrode 21 when the semiconductor device 10 breaks down can be dispersed by the contacts, heat generation due to current concentration is reduced.

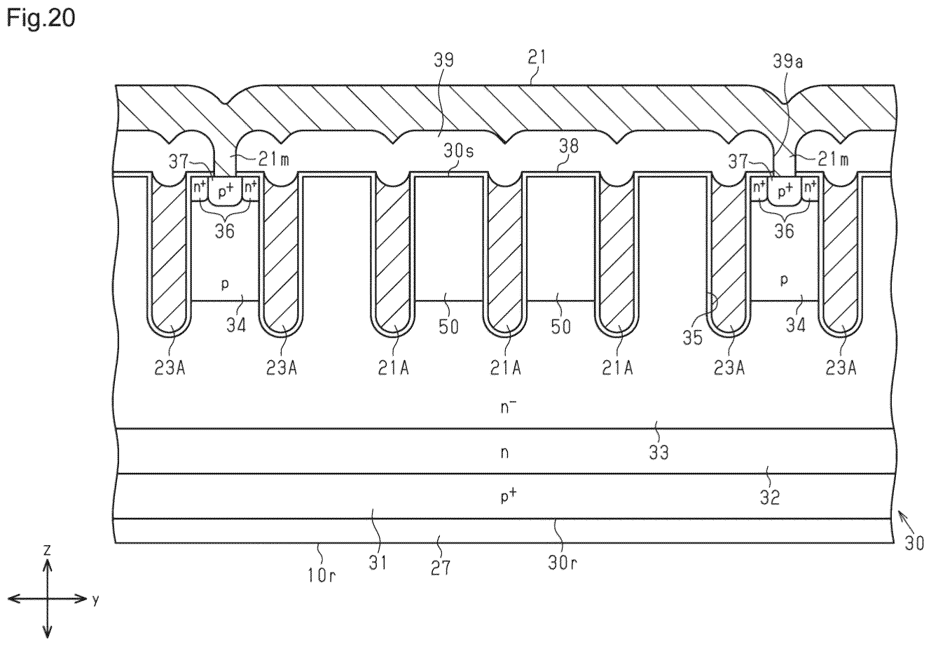

In the above-described embodiment, as shown in FIG. 20, floating regions 50 of the second conductivity type (p-type) may be provided in the drift layer 33 in the main cell region 18M. Each floating region 50 is formed between adjacent ones of the emitter trenches 21A. Each floating region 50 is a semiconductor region that is maintained in an electrically floating state, and is separated from the gate trench 23A by the emitter trenches 21A adjacent to the gate trenches 23A. In the illustrated example, the floating regions 50 are formed so as to have the same depth as the base regions 34. The impurity concentration of the floating regions 50 is in a range of 5×10¹⁵ cm⁻³ to 1×10¹⁸ cm⁻³, for example. Similarly, floating regions 50 are formed in the drift layer 33 in the sense cell region 24A. Since the gate trench 23A and the floating regions 50 are not joined to each other, the stray capacitance between the gate trench 23A and the floating regions 50 is eliminated.

The method of manufacturing the semiconductor device 10 including such floating regions 50 includes a step of forming the floating region 50 between the trenches 35 and a step of forming the well region 34A. The step of forming the floating regions 50 and the step of forming the well region 34A may be performed in the same step. In other words, the floating regions 50 and the well region 34A may be formed simultaneously. This simplifies the manufacturing process of the semiconductor device 10.

The depth of the floating regions 50 can be changed. In one example, the floating regions 50 may be formed so as to cover the bottoms of the emitter trenches 21A. In other words, the floating regions 50 may be formed so as to be closer to the buffer layer 32 than the emitter trenches 21A are.

In the above-described embodiment, the size of the well region 34A can be changed. In one example, one of the opposite ends in the y-direction of the well region 34A that is closer to the main cell region 18M may be located closer to the sense cell region 24A than the first trench 35E of the main cell region 18M is. Also, one of the opposite ends in the y-direction of the well region 34A that is closer to the sense cell region 24A may be located closer to the main cell region 18M than the second trench 35S of the sense cell region 24A is.

In addition, in one example, the well region 34A may be formed so as to be closer to the base region 34 than the bottom 35b of each of the trenches 35E, 35S is. That is, the depth of the well region 34A may be less than those of the trenches 35E, 35S.

In the above-described embodiment, the impurity concentration of the well region 34A may be the same as the impurity concentration of the base region 34. Further, the impurity concentration of the well region 34A may be the same as the impurity concentration of the guard rings 42a to 42d.

In the above-described embodiment, it is sufficient that the emitter electrode 21 has at least one contact 21m among the contacts 21ma to 21me. That is, one to four of the five contacts 21ma to 21me may be omitted.

In the above-described embodiment, the number of end contacts 24CE of the current sense electrode 24 can be changed. In one example, multiple end contacts 24CE may be provided.

In the above-described embodiment, the laminated electrode portion 21n of the emitter electrode 21 and the contacts 21m may be provided separately. The contacts 21m may be provided as embedded electrodes of tungsten (W), for example. The current sense electrode 24 can be modified in the same manner as the emitter electrode 21.

In the above-described embodiment, the arrangement position of the barrier layer 40 can be changed. In one example, the barrier layer 40 may be formed so as to cover each of the electrodes 21 to 25, the surface interconnection of the gate finger 26, the field plates 42e to 42h, and the surface interconnection of the equipotential ring 43. In this case, the barrier layer 40 is not formed on parts of the electrodes 21 to 25 that are exposed by the first to sixth openings 17A to 17F.

In the above-described embodiment, the barrier layer 40, which covers the main cell region 18M, may be omitted. In this case, the insulating film covering the main cell region 18M has a laminated structure of the insulating film 38 and the intermediate insulating film 39. Further, the barrier layer 40, which covers the sense cell region 24A, may be omitted. In this case, the insulating film covering the sense cell region 24A has a laminated structure of the insulating film 38 and the intermediate insulating film 39.

In the above-described embodiment, the barrier layer 40 may be omitted. In this case, both the insulating film covering the sense cell region 24A and the insulating film covering the main cell region 18M have a laminated structure of the insulating film 38 and the intermediate insulating film 39.

In the above-described embodiment, the insulating film covering the sense cell region 24A and the insulating film covering the main cell region 18M may be formed separately.

In the above-described embodiment, the semiconductor device 10 may include a protection diode connected in antiparallel to the temperature sensitive diode 60. The protection diode is accommodated in the diode arrangement portion 21b.

In the above-described embodiment, the temperature sensitive diode 60 may be omitted from the semiconductor device 10. In this case, the diode arrangement portion 21b may be omitted from the emitter electrode 21. In this case, the emitter electrode 21 may be provided with the gate finger accommodating portion 21d instead of the diode arrangement portion 21b. When the temperature sensitive diode 60 is omitted from the semiconductor device 10, the cathode pad 12 and the anode pad 13 may be omitted. Accordingly, the anode 22 may be omitted.

Although the emitter trenches 21A and the gate trenches 23A are arranged alternately in the above-described embodiment, the arrangement of the emitter trenches 21A and the gate trenches 23A is not limited thereto and can be changed.

In each embodiment, the semiconductor device 10 may be a planar gate IGBT instead of the trench gate IGBT.

In each embodiment, the semiconductor device 10 is embodied as an IGBT, but is not limited thereto, and the semiconductor device 10 may be a SiC MOSFET (metal-oxide-semiconductor field-effect transistor) or a Si MOSFET.

In the present disclosure, the term “on” includes the meaning of “above” in addition to the meaning of “on” unless otherwise clearly indicated in the context. Thus, the phrase “A is formed on B” is intended to mean that A may be disposed directly on B in contact with B in the above-described embodiment and also that A may be disposed above B without contacting B in a modified example. In other words, the term “on” does not exclude a structure in which another member is formed between A and B.

The z-direction as referred to in the present disclosure does not necessarily have to be the vertical direction and does not necessarily have to fully conform to the vertical direction. In the structures according to the present disclosure, “upward” and “downward” in the z-direction as referred to in the present description are not limited to “upward” and “downward” in the vertical direction. In an example, the x-direction may conform to the vertical direction. In another example, the y-direction may conform to the vertical direction.

In this specification, “at least one of A and B” should be understood to mean “only A, only B, or both A and B.”

### CLAUSES

The technical aspects that are understood from the above-described embodiment and the modifications will be described below. The reference signs of the elements in the embodiments are given to the corresponding elements in clauses with parentheses. The reference signs used as examples to facilitate understanding, and the elements in each clause are not limited to those elements given with the reference signs.

Clause 1

A semiconductor device (10), including:
an active region (18) that includes a drift layer (33) of a first conductivity type and a body layer (34) of a second conductivity type formed on the drift layer (33); and
an outer peripheral region (19) that surrounds the active region (18), in which
the active region (18) includes:
   a main cell region (18M) that includes a main cell (18A) and through which a main current flows;
   a first insulating film (38, 39, 40) that covers the main cell (18A);
   a first electrode portion (21) that is stacked on the first insulating film (38, 39, 40);
   a sense cell region (24A) that is disposed so as to be separated from the main cell region (18M), includes a sense cell (24B), and through which a sense current corresponding to the main current flows;
   a second insulating film (38, 39, 40) that covers the sense cell (24A); and
   a second electrode portion (24) that is stacked on the second insulating film (38, 39, 40),
a well region (34A) of the second conductivity type is formed between the main cell region (18M) and the sense cell region (24A), and
the first electrode portion (21) and the second electrode portion (24) are electrically connected to the well region (34A).

Clause 2

The semiconductor device according to clause 1, in which the first electrode portion (21) and the second electrode portion (24) are electrically connected to each other via a resistance component of the well region (34A).

Clause 3

The semiconductor device according to clause 1 or 2, in which, as viewed in a thickness direction (z-direction) of the drift layer (33), the well region (34A) includes a part that overlaps with the first electrode portion (21) and a part that overlaps with the second electrode portion (24).

Clause 4

The semiconductor device according to clause 3, in which
the main cell region (18M) and the sense cell region (24A) each include trenches (35) formed from a surface (30s) of the body layer (34) toward the drift layer (33), and
the well region (34A) is formed between a first trench (35E) and a second trench (35S), the first trench (35E) being one of the trenches (35) of the main cell region (18M) that is closest to the sense cell region (24A), and the second trench (35S) being one of the trenches (35) of the sense cell region (24A) that is closest to the main cell region (18M).

Clause 5

The semiconductor device according to clause 4, in which
the well region (34A)
   is formed so as to be closer to the drift layer (33) than a bottom (35b) of the first trench (35E) and a bottom (35b) of the second trench (35S) are, and
   is formed so as to cover at least a part of the bottom (35b) of the first trench (35E) and at least a part of the bottom (35b) of the second trench (35S).

Clause 6

The semiconductor device according to any one of clauses 1 to 5, in which an impurity concentration of the well region (34A) is lower than an impurity concentration of the body layer (33).

Clause 7

The semiconductor device according to any one of clauses 1 to 6, in which, as viewed in a thickness direction (z-direction) of the drift layer (33), the well region (34A) is formed so as to surround the sense cell region (18M).

Clause 8

The semiconductor device according to clause 7, in which
the second electrode portion (24) includes a sense contact (24C) connected to the well region (34A), and
the sense contact (24C) includes a sense end contact (24CE) that is formed at an end of the second electrode portion (24) closest to the main cell region (18M).

Clause 9

The semiconductor device according to clause 8, in which
the first electrode portion (21) includes a main contact (21m/21ma-21me) connected to the well region (34A), and
the main contact (21m/21ma-21me) is formed so as to surround the sense cell region (24A).

Clause 10

The semiconductor device according to clause 9, in which
the main contact (21m) includes a main end contact (21ma) that is provided at a position facing the sense end contact (24CE) as viewed in the thickness direction (z-direction) of the drift layer (33), and
the main end contact (21ma) and the sense end contact (24CE) respectively include multiple main end contacts (21ma) and multiple sense end contacts (24CE), and
a number of the main end contacts (21ma) is greater than a number of the sense end contacts (24CE).

Clause 11

The semiconductor device according to any one of clauses 1 to 10, in which
the outer peripheral region (19) includes a termination structure (42),
the termination structure (42) includes a guard ring (42a-42d) of the second conductivity type, and
an impurity concentration of the well region (34A) is lower than an impurity concentration of the guard ring (42a-42d).

Clause 12

The semiconductor device according to any one of clauses 1 to 11, in which the first insulating film (38, 39, 40) and the second insulating film (38, 39, 40) are formed by a common insulating film.

Clause 13

A method of manufacturing a semiconductor device, the method including:
forming a drift layer (33) of a first conductivity type;
forming a body layer (34) of a second conductivity type on the drift layer (33);
forming a main cell region (18M) that includes a main cell (18A) and through which a main current flows;
forming a sense cell region (24A) that is disposed so as to be separated from the main cell region (18M), includes a sense cell (24B), and through which a sense current corresponding to the main current flows;
forming a well region (34A) of the second conductivity type between the main cell region (18M) and the sense cell region (24A);
forming a first insulating film (38, 39, 40) that covers the main cell (18A);
stacking a first electrode portion (21) on the first insulating film (38, 39, 40);
forming a second insulating film (38, 39, 40) that covers the sense cell (24B); and
stacking a second electrode portion (24) on the second insulating film (38, 39, 40), in which
the first insulating film (38, 39, 40) and the second insulating film (38, 39, 40) each include a part that covers the well region (34A),
the stacking the first electrode portion (21) on the first insulating film (38, 39, 40) includes:
   forming a main-side opening (39a) that exposes the well region (34A) in the part of the first insulating film (38, 39, 40) that covers the well region (34A); and
   forming a main contact (21m) in contact with the well region (34A) by embedding a part of the first electrode portion (21) in the main-side opening (39a), and
the stacking the second electrode portion (24) on the second insulating film (38, 39, 40) includes:
   forming a sense-side opening (39b) that exposes the well region (34A) in the part of the second insulating film (38, 39, 40) that covers the well region (34A); and
   forming a sense contact (24C) in contact with the well region (34A) by embedding a part of the second electrode portion (24) in the sense-side opening (39b).

Clause 14

The method of manufacturing the semiconductor device according to clause 13, further including:
forming a termination structure (42) in an outer peripheral region (19) surrounding both the main cell region (18M) and the sense cell region (24A), in which
the forming the termination structure (42) includes forming a guard ring (42a-42d) of the second conductivity type, and
the formation of the well region (34A) and the formation of the guard ring (42a-42d) are performed in a same process.

Clause 15

The method of manufacturing the semiconductor device according to clause 13 or 14, further including:
forming trenches (34) in the main cell region (18M) and the sense cell region (24A) from a surface (30s) of the body layer (33) toward the drift layer (33); and
forming a floating region (50) of the second conductivity type between the trenches (35),
in which the formation of the well region (34A) and the formation of the floating region (50) are performed in a same process.

1. A semiconductor device, including:
an active region that includes a drift layer of a first conductivity type and a body layer of a second conductivity type formed on the drift layer; and
an outer peripheral region that surrounds the active region, wherein
the active region includes:
a main cell region that includes a main cell and through which a main current flows;
a first insulating film that covers the main cell;
a first electrode portion that is stacked on the first insulating film;
a sense cell region that is disposed so as to be separated from the main cell region, includes a sense cell, and through which a sense current corresponding to the main current flows;
a second insulating film that covers the sense cell; and
a second electrode portion that is stacked on the second insulating film,
a well region of the second conductivity type is formed between the main cell region and the sense cell region, and
the first electrode portion and the second electrode portion are electrically connected to the well region.

2. The semiconductor device according to claim 1, wherein the first electrode portion and the second electrode portion are electrically connected to each other via a resistance component of the well region.

3. The semiconductor device according to claim 1, wherein, as viewed in a thickness direction of the drift layer, the well region includes a part that overlaps with the first electrode portion and a part that overlaps with the second electrode portion.

4. The semiconductor device according to claim 3, wherein
the main cell region and the sense cell region each include trenches formed from a surface of the body layer toward the drift layer, and
the well region is formed between a first trench and a second trench, the first trench being one of the trenches of the main cell region that is closest to the sense cell region, and the second trench being one of the trenches of the sense cell region that is closest to the main cell region.

5. The semiconductor device according to claim 4, wherein
the well region
is formed so as to be closer to the drift layer than a bottom of the first trench and a bottom of the second trench are, and
is formed so as to cover at least a part of the bottom of the first trench and at least a part of the bottom of the second trench.

6. The semiconductor device according to claim 1, wherein an impurity concentration of the well region is lower than an impurity concentration of the body layer.

7. The semiconductor device according to claim 1, wherein, as viewed in a thickness direction of the drift layer, the well region is formed so as to surround the sense cell region.

8. The semiconductor device according to claim 7, wherein
the second electrode portion includes a sense contact connected to the well region, and
the sense contact includes a sense end contact that is formed at an end of the second electrode portion closest to the main cell region.

9. The semiconductor device according to claim 8, wherein
the first electrode portion includes a main contact connected to the well region, and
the main contact is formed so as to surround the sense cell region.

10. The semiconductor device according to claim 9, wherein
the main contact includes a main end contact that is provided at a position facing the sense end contact as viewed in the thickness direction of the drift layer, and
the main end contact and the sense end contact respectively include multiple main end contacts and multiple sense end contacts, and
a number of the main end contacts is greater than a number of the sense end contacts.

11. The semiconductor device according to claim 1, wherein
the outer peripheral region includes a termination structure,
the termination structure includes a guard ring of the second conductivity type, and
an impurity concentration of the well region is lower than an impurity concentration of the guard ring.

12. The semiconductor device according to claim 1, wherein the first insulating film and the second insulating film are formed by a common insulating film.

13. A method of manufacturing a semiconductor device, the method comprising:
forming a drift layer of a first conductivity type;
forming a body layer of a second conductivity type on the drift layer;
forming a main cell region that includes a main cell and through which a main current flows;
forming a sense cell region that is disposed so as to be separated from the main cell region, includes a sense cell, and through which a sense current corresponding to the main current flows;
forming a well region of the second conductivity type between the main cell region and the sense cell region;
forming a first insulating film that covers the main cell;
stacking a first electrode portion on the first insulating film;
forming a second insulating film that covers the sense cell; and
stacking a second electrode portion on the second insulating film, wherein
the first insulating film and the second insulating film each include a part that covers the well region,
the stacking the first electrode portion on the first insulating film includes:
forming a main-side opening that exposes the well region in the part of the first insulating film that covers the well region; and
forming a main contact in contact with the well region by embedding a part of the first electrode portion in the main-side opening, and
the stacking the second electrode portion on the second insulating film includes:
forming a sense-side opening that exposes the well region in the part of the second insulating film that covers the well region; and
forming a sense contact in contact with the well region by embedding a part of the second electrode portion in the sense-side opening.

14. The method of manufacturing the semiconductor device according to claim 13, further comprising:
forming a termination structure in an outer peripheral region surrounding both the main cell region and the sense cell region, wherein
the forming the termination structure includes forming a guard ring of the second conductivity type, and
the formation of the well region and the formation of the guard ring are performed in a same process.

15. The method of manufacturing the semiconductor device according to claim 13, further comprising:
forming trenches in the main cell region and the sense cell region from a surface of the body layer toward the drift layer; and
forming a floating region of the second conductivity type between the trenches,
wherein the formation of the well region and the formation of the floating region are performed in a same process.
